(19) United States
(12) Patent Application Publication
(10) Pub. No.: US 2014/0068169 A1
(43) Pub. Date: Mar. 6, 2014

(54) Independent Threading Of Memory Devices Disposed On Memory Modules

(71) Applicant: Rambus Inc., Sunnyvale, CA (US)

(72) Inventors: Frederick Ware, Los Altos Hills, CA (US); Craig E. Hampel, Los Altos, CA (US); Ian Shaeffer, Los Gatos, CA (US); Scott C. Best, Palo Alto, CA (US)

(21) Appl. No.: 13/923,184

(22) Filed: Jun. 20, 2013

Related U.S. Application Data
(63) Continuation of application No. 12/920,811, filed on Sep. 2, 2010, now abandoned.
(60) Provisional application No. 61/041,187, filed on Mar. 31, 2008.

(51) Int. Cl. G11C 7/10

(52) U.S. Cl. CPC G11C 7/1072
USPC 711/105

(57) ABSTRACT

A memory module includes a substrate having signal lines thereon that form a control path and a plurality of data paths. A plurality of memory devices are mounted on the substrate. Each memory device is coupled to the control path and to a distinct data path. The memory module includes control circuitry to enable each memory device to process a distinct respective memory access command in a succession of memory access commands and to output data on the distinct data path in response to the processed memory access command.

This disclosure is a continuation of U.S. Utility patent application Ser. No. 12/920,811, filed as a national stage entry of International Application No. PCT/US09/36161 on Sep. 2, 2010 (under 35 USC §371); International Application No. PCT/US09/36161 was filed on Mar. 5, 2009 as a non-provisional of U.S. Provisional Patent Application No. 61/041,187, which was filed on Mar. 31, 2008. Each of these prior applications was filed on behalf of inventors Frederick Ware, Craig E. Hampel, Ian Shaeffer and Scott C. Best and entitled “Independent Threading of Memory Devices Disposed On Memory Modules.” Each of these prior applications is hereby incorporated by reference.

### TECHNICAL FIELD

The disclosed embodiments relate generally to memory systems having memory modules, and more particularly, to high-speed memory modules with independently threaded memory devices.

### BACKGROUND

Designing memory systems including memory modules presents significant engineering challenges. For example, increasing signal rates present challenges for data bus architectures. Designers are challenged to reduce operating power and to improve processing efficiency for multithreaded systems. Efficiently implementing error-correction coding (ECC) also presents difficulties.

### BRIEF DESCRIPTION OF THE DRAWINGS

FIGS. 1A-1D are schematic diagrams illustrating memory systems in accordance with some embodiments.

FIGS. 2A and 2B are cross-sectional diagrams of memory systems in accordance with some embodiments.

FIGS. 3A-3D illustrate timing diagrams for memory access commands in accordance with some embodiments.

FIG. 4A is a schematic diagram of variable-delay chip select (CS) circuitry in a memory device in accordance with some embodiments.

FIG. 4B is a schematic diagram of a memory module having a plurality of CS signal lines in accordance with some embodiments.

FIGS. 5A and 5B illustrate CS timing in accordance with some embodiments.

FIG. 6A is a block diagram of a portion of a memory controller in accordance with some embodiments.

FIGS. 6B and 6E illustrate timing diagrams for a memory controller in accordance with some embodiments.

FIGS. 6C and 6D illustrate address decoding in accordance with some embodiments.

FIG. 7 is a block diagram of a portion of a memory device in accordance with some embodiments.

FIG. 8A illustrates address decoding for memory that includes ECC syndromes in accordance with some embodiments.

FIG. 8B illustrates a timing diagram for memory access commands directed to a memory device that stores ECC syndromes along with corresponding data in accordance with some embodiments.

FIG. 8C illustrates a timing diagram for a configuration in which ECC syndromes are stored in a separate dedicated memory device on a module in accordance with some embodiments.

FIG. 9A is a flow diagram illustrating a method of operating a plurality of memory devices disposed on a memory module in accordance with some embodiments.

FIGS. 9B and 9C are flow diagrams illustrating a method of controlling memory devices in accordance with some embodiments.

FIGS. 10A-10D are block diagrams illustrating memory modules that include one or more buffer devices in accordance with some embodiments.

FIG. 11 is a block diagram of an embodiment of a system for storing computer readable files containing software descriptions of circuits for implementing memory systems, memory controllers, and memory devices in accordance with some embodiments.

FIGS. 12A-12C are block diagrams of a memory device in accordance with some embodiments.

Like reference numerals refer to corresponding parts throughout the drawings.

### DESCRIPTION OF EMBODIMENTS

In some embodiments, a memory module includes a substrate having signal lines thereon that form a control path and a plurality of data paths. A plurality of memory devices are mounted on the substrate. Each memory device is coupled to the control path and to a distinct data path. The memory module includes control circuitry to enable each memory device to process a distinct respective memory access command in a succession of memory access commands and to output data on the distinct data path in response to the processed memory access command.

In some embodiments, a plurality of memory devices disposed on a memory module is operated in a first mode of operation. Each memory device is coupled to a common control path and a distinct data path. Each memory device receives, via the control path, a succession of memory access commands and processes a distinct respective memory access command in the succession. In response to each processed memory access command, data is transferred from the memory device that processed the memory access command onto the distinct data path corresponding to the memory device.

In some embodiments, a method of operation is performed for a plurality of memory devices disposed on a memory module. The memory module includes one or more buffer devices coupled to the memory devices. Each memory device is coupled to a common control path and a distinct data path. In the method, a succession of memory access commands is received via the control path. A chip select (CS) signal to be provided to the memory devices to enable respective memory devices to process respective memory access commands is buffered via the one or more buffer devices. Each respective memory device receives the CS signal during a distinct clock cycle. At each respective memory device, a distinct respective memory access command in the succession is processed. The distinct respective memory access command corresponds to the distinct clock cycle during which the respective memory device receives the CS signal. In response to each processed memory access command, data is transferred from the memory device that processed the memory access command onto the distinct data path corresponding to the memory device.

In some embodiments, a memory controller for controlling multiple memory devices disposed on a first module includes a first plurality of queues. Each queue in the first plurality queues addresses and data corresponding to a respective memory device on the first module. The memory controller also includes a first scheduling circuit coupled to the first plurality of queues, to provide addresses from respective queues of the first plurality of queues; a first control path interface coupled to the first scheduling circuit, to transmit control signals including the addresses to the first module; and a first plurality of data path interfaces, coupled to respective queues in the first plurality of queues, to transmit and receive data to and from respective memory devices on the first module.

In some embodiments, a method of controlling multiple memory devices disposed on a first memory module includes, in a first mode of operation, transmitting successive memory access commands to each memory device via a first common control path. The successive memory access commands are directed to respective memory devices on the first memory module in sequence. In response to each memory access command, data is received from the respective memory device via a respective data path of a first plurality of parallel data paths.

In some embodiments, a memory system includes signal lines that form a first control path, a second control path, a first plurality of data paths, and a second plurality of data paths. A first memory module socket is coupled to the first control path and to the first plurality of data paths; a second memory module socket is coupled to the second control path and to the second plurality of data paths. A memory controller is coupled to the signal lines. A first memory module, having multiple memory devices, is inserted into the first memory module socket; each memory device is coupled through the first socket to the first control path and to a distinct data path of the first plurality of data paths. The first memory module includes control circuitry to enable each memory device of the first memory module to process a distinct respective memory access command in a first succession of memory access commands received from the memory controller via the first control path and to output data to the controller via the distinct data path in response to the processed memory access command.

Reference will now be made in detail to embodiments, examples of which are illustrated in the accompanying drawings. In the following detailed description, numerous specific details are set forth in order to provide a thorough understanding of the present invention. However, it will be apparent to one of ordinary skill in the art that the present invention may be practiced without these specific details. In other instances, well-known methods, procedures, components, and circuits have not been described in detail so as not to unnecessarily obscure aspects of the embodiments.

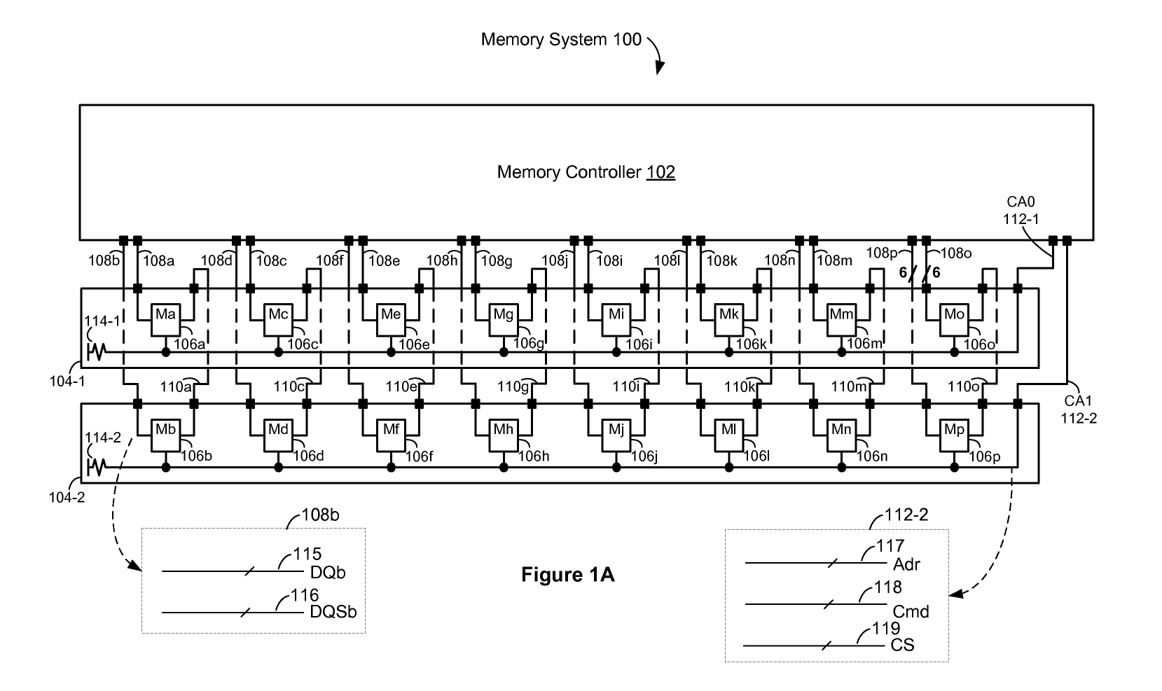

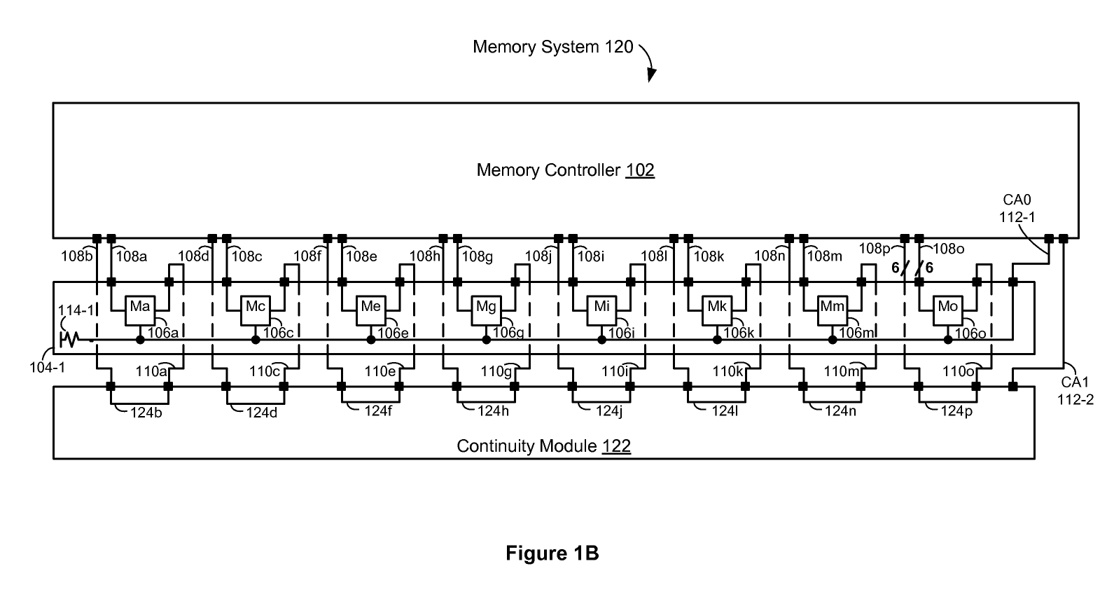

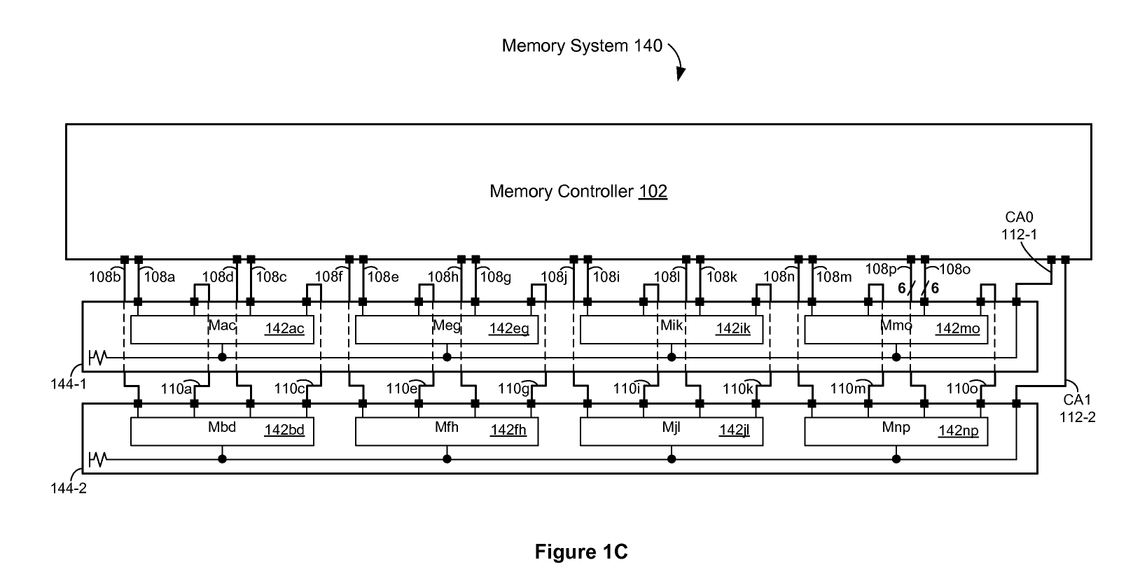

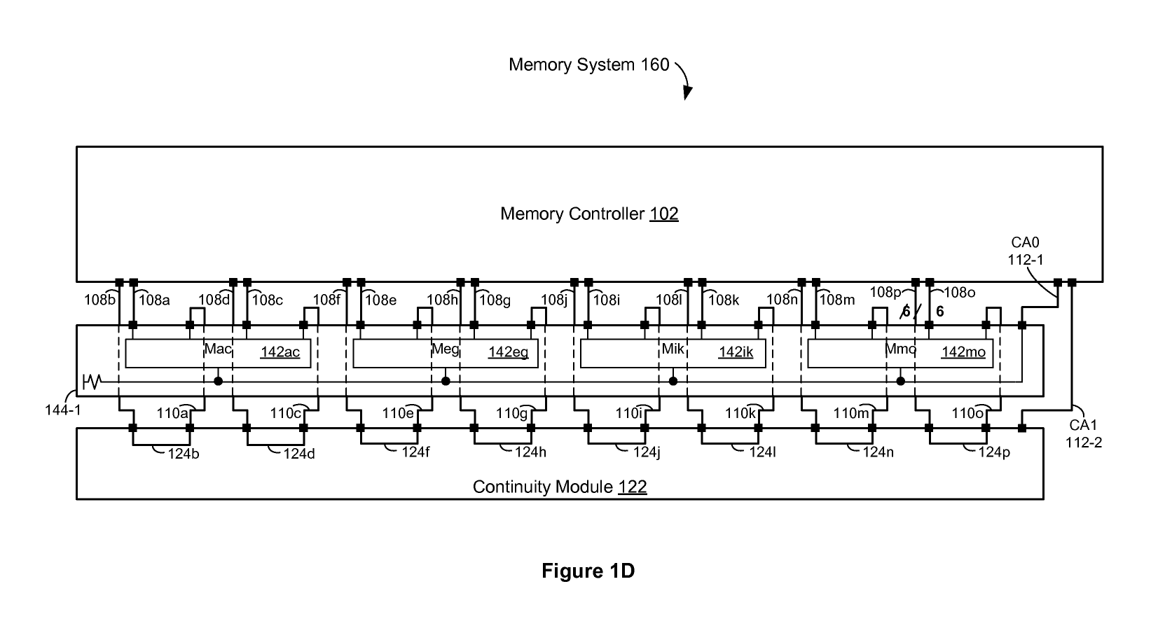

FIG. 1A is a schematic diagram illustrating a memory system 100 in accordance with some embodiments. The system 100 includes a memory controller 102 coupled to two memory modules 104-1 and 104-2. In some embodiments, the memory controller 102 is implemented as a single integrated circuit (IC). In some embodiments, the memory modules 104 are dual-inline memory modules (DIMMs). Eight memory devices (e.g., DRAM chips) 106 are mounted on each module 104. The memory system 100 is part of a larger electronic system. For example, the memory controller 102 is coupled to a microprocessor and provides data retrieved from the memory devices 106 to the microprocessor.

A distinct data path 108 couples each memory device 106 to the controller 102. The signal lines in each data path 108 form point-to-point connections between the corresponding memory device 106 and the controller 102. In some embodiments, each data path 108 includes a plurality of data (DQ) signal lines and a plurality of strobe (DQS) signal lines. For example, a DQS signal line 116 may correspond to two DQ signal lines 115 and provide timing information regarding when to sample the DQ signals on the two corresponding DQ signal lines 115. In the system 100, the memory devices 106 are configured to operate in ×4 mode, such that each 6-bit wide data path 108 in FIG. 1A includes 4 DQ signal lines 115 and 2 DQS signal lines 116. Each data path 108 thus couples 4 DQ pins and 2 DQS pins on a memory 106 to corresponding pins on the controller 102. In another example, a respective data path (e.g., 108b) has 4n DQ signal lines 115 and 2n DQS signal lines, where n is a positive integer (e.g., n=1 or 2 or 3 or 4, etc.).

A first control path (CA0) 112-1 couples the memory devices 106 on the first module 104-1 to the memory controller 102. Similarly, a second control path (CA1) 112-2 couples the memory devices 106 on the second module 104-2 to the memory controller 102. In some embodiments, each control path 112 includes address signal lines 117, command signal lines 118, and one or more chip select (CS) signal lines 119. An asserted CS signal enables a memory device 106 to process received addresses and commands. Control signals transmitted from the memory controller 102 to the first memory module 104-1 via CA0 112-1 may be independent of control signals transmitted to the second memory module 104-2 via CA1 112-2.

Clock signals are provided to the modules 104 via first and second clock paths (not shown).

A memory access command provided by the controller 102 via a control path 112 is received by each memory device 106 on the respective module 104, since the memory devices on the module are coupled in common to the control path 112. In some embodiments, however, a memory access command is directed to a particular memory device on a memory module, such that the particular memory device performs the memory access command and the other memory devices disregard the access command. The memory device 106 that performs the memory access command transfers the corresponding data to the controller 102 via the data path 108 coupled to the device. Sequential memory access commands may be directed to successive memory devices 106 on the module 104. When all of the memory devices on a module 104 are successively accessed in this way, this mode of access is sometimes called accessing the memory devices in round robin order. “Round robin” ordering can also apply to a subset of the memory devices on a module. Each memory device thus is capable of operating independently of the other memory devices, allowing independent threading of the devices.

A plurality of data paths 110 couple the first module 104-1 to the second module 104-2. For example, data path 110a couples memory device 106a to memory device 106b. In the system 100, in which two memory modules are present, the data paths 110 are not used. For example, the data paths 110 are coupled to DQ pins on the corresponding memory devices 106 that are tristated.

The signal lines in the control paths 112, data paths 108, and data paths 110 may be implemented as traces and vias on the substrates of the modules 104 and on one or more printed circuit boards to which the modules 104 and memory controller 102 are connected. In some embodiments, termination resistors 114 terminate the control path 112 on the corresponding module 104.

FIG. 1B is a schematic diagram illustrating a memory system 120 in which the second memory module 104-2 of system 100 has been replaced with a continuity module 122 in accordance with some embodiments. The continuity module 122 includes signal paths 124 that short the data paths 110 to corresponding data paths 108. For example, signal path 124b shorts data path 110a to data path 108b, providing a complete path by which a memory device 106 may communicate with the controller. The signal paths 124 are implemented as traces or a combination of traces and vias on the continuity module 124. The continuity module 122 enables the memory devices 106 on the memory module 104-1 to be configured in ×8 mode instead of ×4 mode. For example, memory device 106a can simultaneously transmit or receive four data bits via data path 108a and four data bits via the combination of paths 108b, 124b, and 110a.

FIG. 1C is a schematic diagram illustrating a memory system 140 that includes the memory controller 102 coupled to two memory modules 144-1 and 144-2 in accordance with some embodiments. Four memory devices 142 are mounted on each module 144. Each memory device 142 is configured to operate in ×8 mode. For example, memory device 142ac may simultaneously transmit or receive four data bits via data path 108a and four data bits via data path 108c. As in FIG. 1A, control path CA0 112-1 couples the memory devices 142 on the first module 144-1 to the memory controller 102 and control path CA1 112-2 couples the memory devices 142 on the second module 144-2 to the memory controller 102. Control signals transmitted from the memory controller 102 to the first memory module 144-1 via CA0 112-1 may be independent of control signals transmitted to the second memory module 144-2 via CA1 112-2. The control signals may include address signals, command signals, and CS signals.

FIG. 1D is a schematic diagram illustrating a memory system 160 in which the second memory module 144-2 of system 140 (FIG. 1C) has been replaced with a continuity module 122, in accordance with some embodiments. As in memory system 120 (FIG. 1B), the signal paths 124 short the data paths 110 to corresponding data paths 108. The continuity module 122 thus enables the memory devices 142 on the memory module 144-1 to be configured in ×16 mode instead of ×8 mode. For example, memory device 142a can simultaneously transmit or receive four data bits via data path 108a, four data bits via data path 108c, four data bits via the combination of paths 108b, 124b, and 110a, and four data bits via the combination of paths 108d, 124d, and 110c.

FIGS. 1A-1D illustrate data paths 108 with signal lines that form point-to-point connections between a memory device and a memory controller. In some embodiments, however, data path signal lines connect two or more memory devices to a memory controller. For example, a memory module may include two or more memory devices arranged in a stacked configuration at a particular location on the module. The two or more stacked devices may share multi-drop data path signal lines.

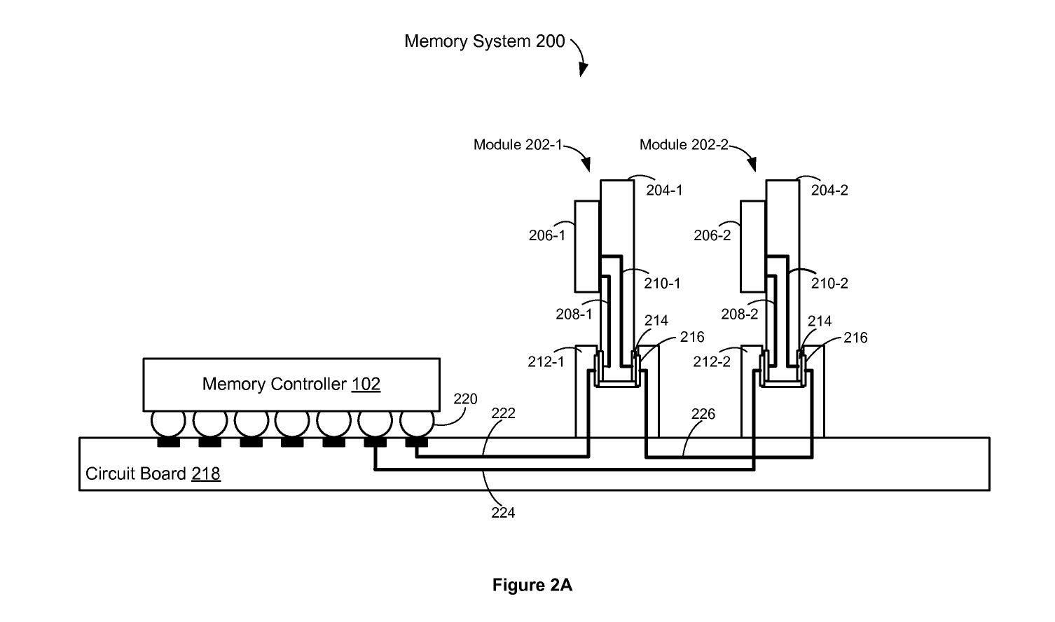

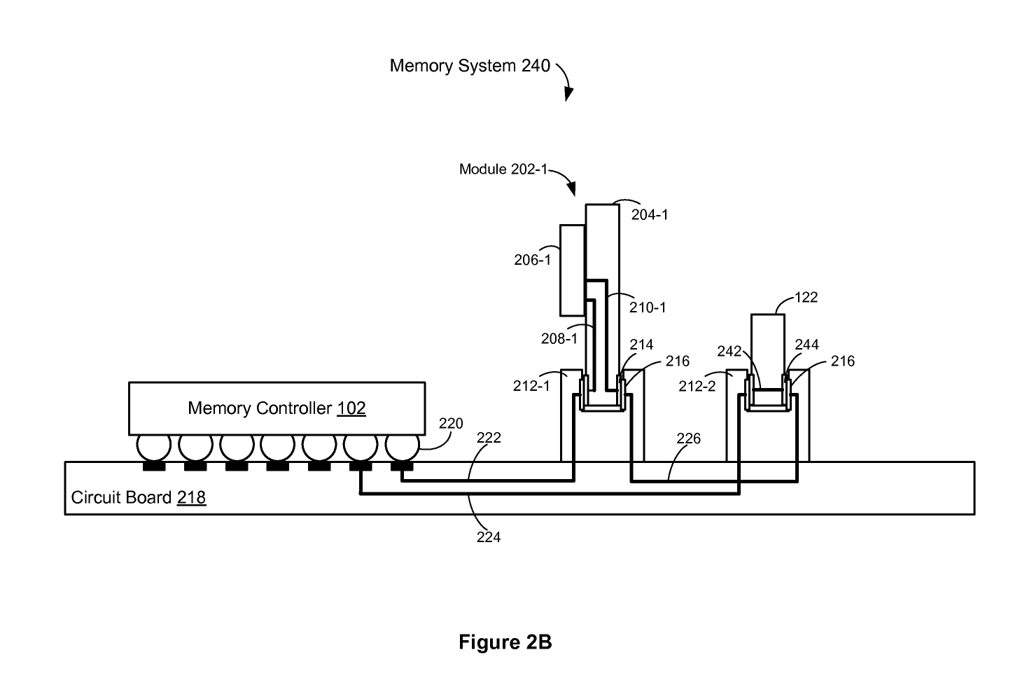

FIG. 2A is a cross-sectional diagram of a memory system 200 in accordance with some embodiments. The drawings in FIGS. 2A and 2B are not to scale, and some elements (e.g., solder balls 220) are disproportionately sized to enable the reader to see them. The memory system 200 is a possible implementation of memory systems such as systems 100 (FIG. 1A) or 140 (FIG. 1C). A memory controller 102 is connected to a circuit board 218. For example, solder balls 220 electrically connect the controller 102 to the board 218. Memory modules 202-1 and 202-2 are inserted into respective sockets 212-1 and 212-2, which in turn are connected to the circuit board 218. Each memory module 202 includes a substrate 204 and memory devices 206 mounted on the substrate. The memory devices 206 are electrically connected to signal lines (e.g., 208 and 210) in the substrate 204 by contacts such as metal leads or solder balls (not shown). Examples of the memory devices 206 include devices 106 (FIG. 1A) or 142 (FIG. 1C). Examples of the memory modules 202 include modules 104 (FIG. 1A) or 144 (FIG. 1C).

Signal lines 222 and 224 respectively couple the first socket 212-1 and the second socket 212-2 to the controller 102. Signal lines 226 couple the first socket 212-1 to the second socket 212-2. The data paths 108 and control paths 112 thus correspond to a plurality of signal lines 222 or 224, while the data paths 110 correspond to a plurality of signal lines 226. The signal lines 222, 224, and 226 may be routed through traces and vias in the circuit board 218 and leads in the socket 212. Socket contacts 214 and module edge contacts 216 couple the signal lines 222, 224, or 226 to signal lines 208 or 210 on the module substrate 204.

FIG. 2B is a cross-sectional diagram of a memory system 240 in accordance with some embodiments. The memory system 240 is a possible implementation of memory systems such as systems 120 (FIG. 1B) or 160 (FIG. 1D). In the memory system 240, the second module 202-2 of system 200 has been replaced by a continuity module 122, in which the signal paths 124 are implemented using signal lines 242 that connect edge contacts 244. The continuation module 124 thus couples memory devices 206 on the module 202-1, through the signal lines 226, to the signal lines 224 and thereby to the controller 102.

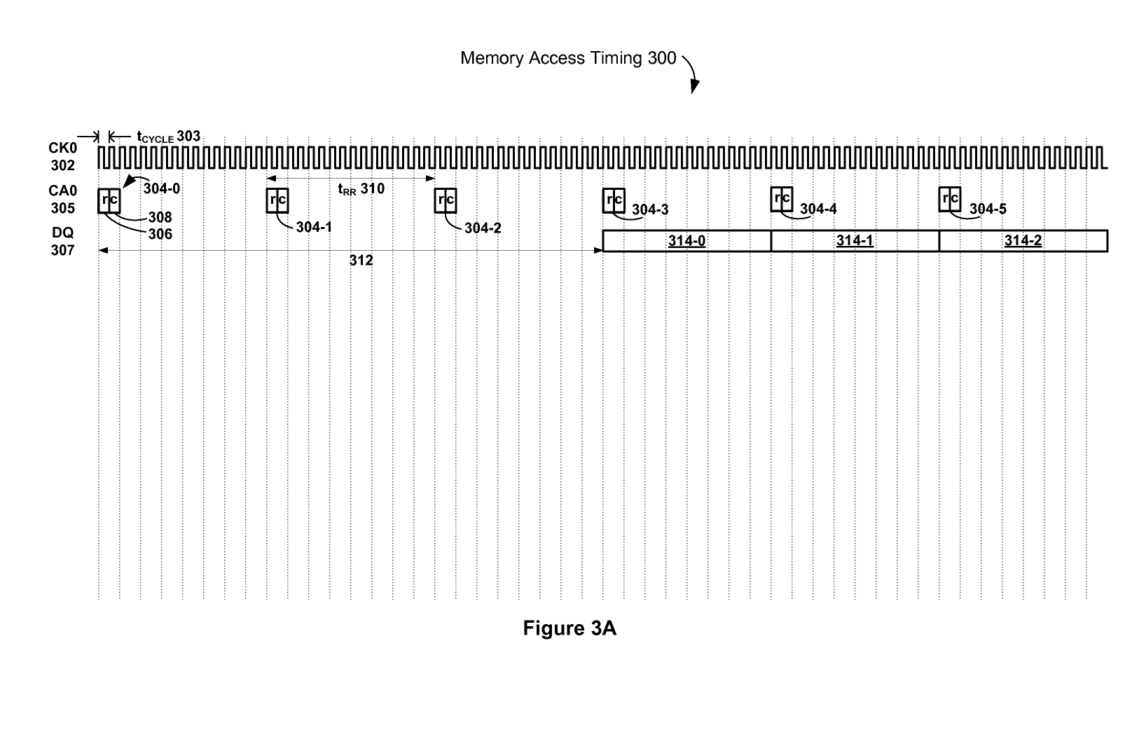

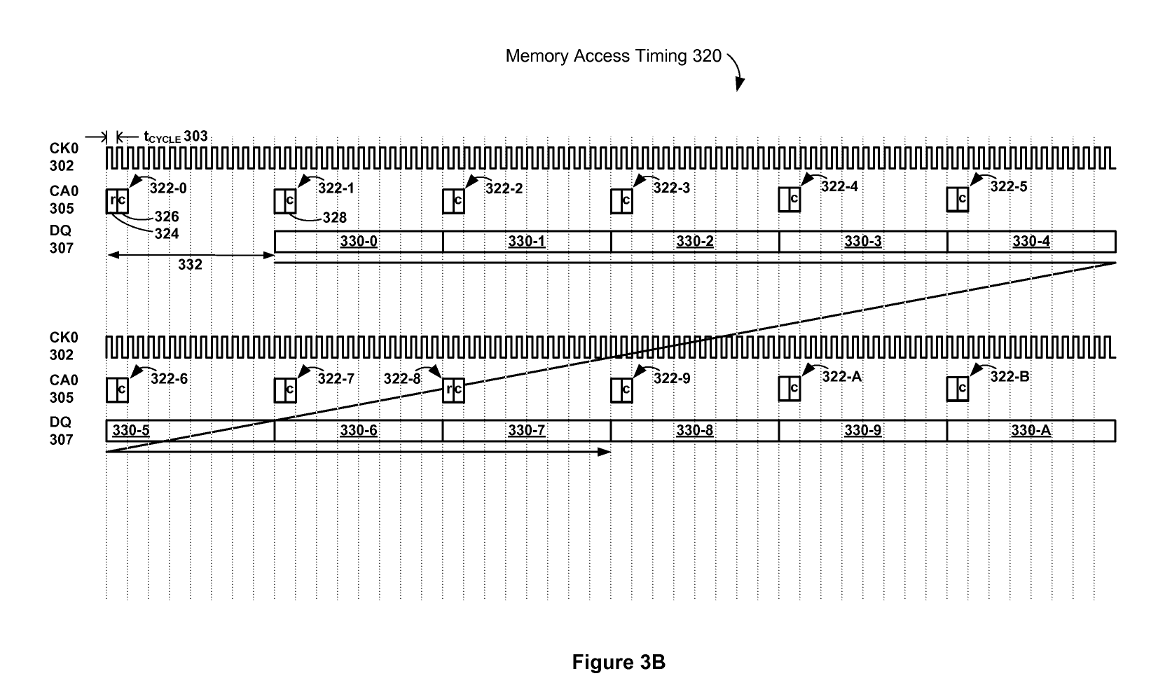

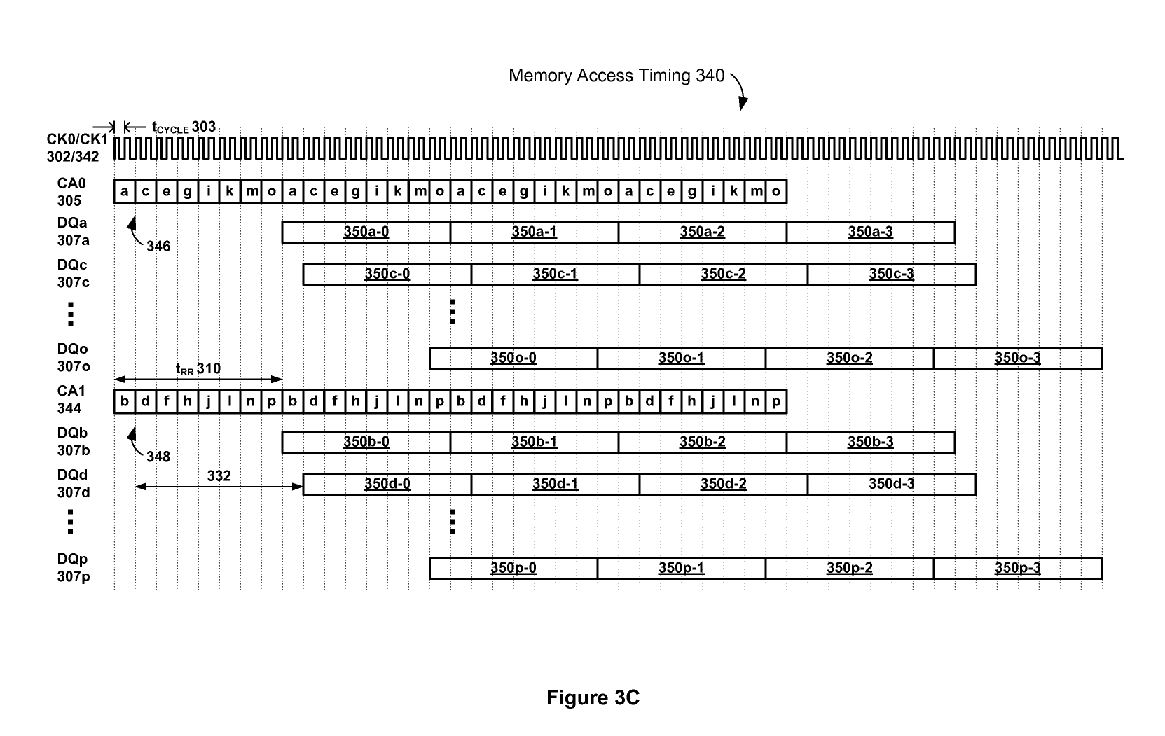

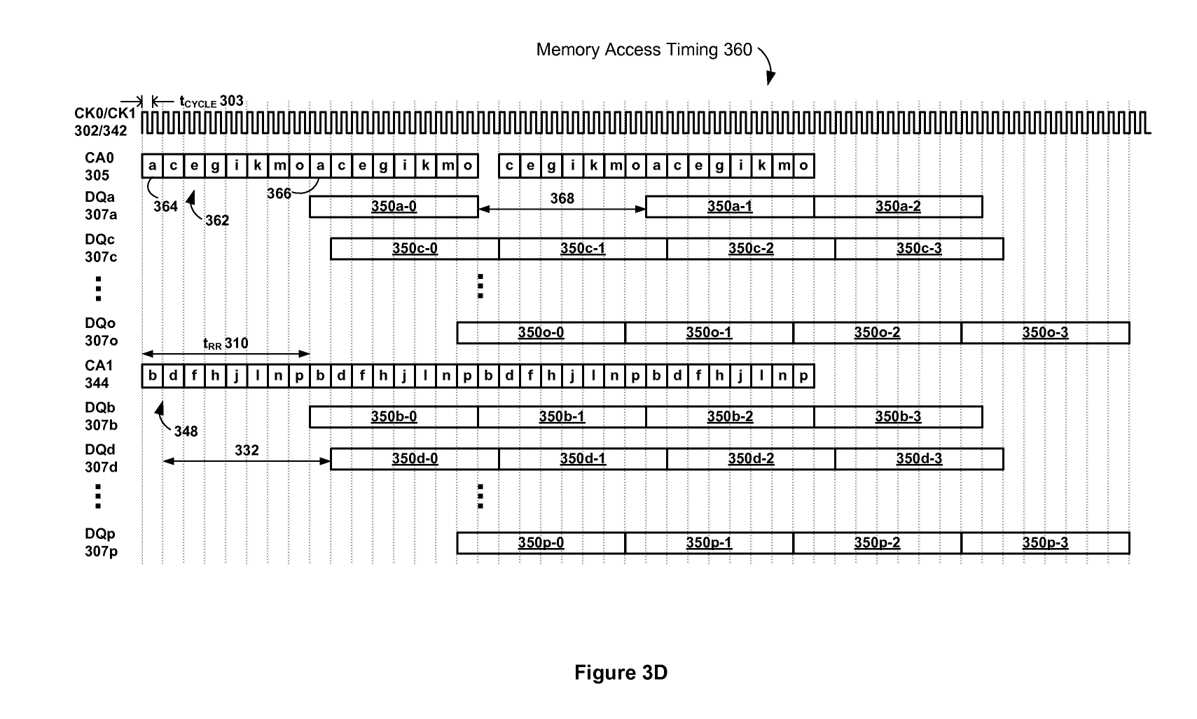

FIG. 3A illustrates a timing diagram 300 for memory access commands directed to a memory device on a memory module in accordance with some embodiments. The timing diagram 300 includes a clock signal (CK0) 302, a command signal (CA0) 305, and a data (DQ) signal 307. For example, the memory controller 102 issues memory access commands directed at a particular memory device 106 or 142 on a memory module 104 or 144. The memory access commands are provided via a control path 112 to each memory device 106 or 142 on the memory module 104 or 144, but are directed to a particular device 106 or 142. The remaining devices 106 or 142, to which the memory access commands are not directed, disregard the commands.

The clock signal (CK0) 302 is provided to the memory device. In some embodiments, the clock signal has a frequency of at least 1.6 GHz and a corresponding clock period 303 of 0.625 ns or less.

In some embodiments, a memory access command 304 includes a row access command 306 and a column access command 308. For example, memory access command 304 is shown as a two-cycle command, with one clock cycle for the row access command 306 and one clock cycle for the column access command 308. In some embodiments, the column access command 308 is a two-column burst command instructing the memory successively to access two columns in the row specified by the row access command 306. In some embodiments, column addresses for burst commands are generated in a sequential order or in an interleaved order. In some embodiments, the order of generation of the column addresses is determined by a mode setting in the memory device and/or by one or more bits (e.g., address bits) provided to the memory device for the column access command.

Successive memory access commands 304 directed to the memory device may be issued with a period t_{RR} 310 between commands, assuming that the commands are directed to separate banks within the memory device. If the commands are directed to the same bank, or more specifically to separate rows within the same bank, bank interference occurs, resulting in an extra delay to pre-charge the bank and to sense a new row within the bank. This extra delay results in an idle period during which the device does not output data. The parameter t_{RR} 310 may be defined as the required or normal time between successive memory access commands, as measured from the start time of one command to the start time of the next command, to the same row and bank of a memory device. For purposes of illustration, in one embodiment t_{RR} 310 is approximately 10 ns, corresponding to sixteen (16) clock cycles between commands 304 at 1.6 GHz. In this example, there are eight two-cycle time slots for commands on each control path of the memory module. More generally, for each control path (e.g., CA0 112-1, and CA1 112-2) there are T (e.g., 4, 5, 8, 9, 16, 18, etc.) time slots for commands per time period t_{RR} 310, with each time slot occupying a fixed or predefined number of clock cycles. In the embodiments described in detail here, the number of time slots T is equal to the number of memory devices responsive to commands on each control path. However, in some other embodiments the number of time slots T is not equal to the number of memory devices responsive to commands on each control path. For example, in one embodiment T is equal to four while the number of memory devices responsive to each control path is eight. In yet another example, if T is greater than the number of memory devices responsive to commands on each control path, then some of the time slots will go unused.

The memory device outputs a complete data word in response to each memory access command 304. Assuming that each column in the memory device is 64 bits wide and that the memory device is a double data rate (DDR) device configured for ×4 operation (e.g., memory device 106, FIG. 1A), the 128-bit data word 314-0 for the two-column burst command 308 is output over a period of sixteen (16) clock cycles. Eight bits are output each clock cycle, four on the rising clock edge and four on the falling clock edge. Given a clock frequency of 1.6 GHz, each DQ pin on the memory device has a data rate of 3200 Mb/s. For the example of memory device 106, the output is provided to the memory controller 102 via the data path 108 for the device (e.g., data path 108a for device 106a). A latency 312 is associated with each memory access command 304. In one example, the latency 312 is approximately 30 ns, corresponding to 48 clock cycles at 1.6 GHz

Because the output period for each data word 314 is equal to t_{RR} 310, the memory device can execute successive memory access commands 304 with no interruption in its output. As shown in FIG. 3A, there is no idle period between output data words 314-0, 314-1, and 314-2, which are provided in response to memory access commands 304-0, 304-1, and 304-2 respectively.

Multiple two-column burst commands may be performed for a given row access command, as illustrated in timing diagram 320 (FIG. 3B) in accordance with some embodiments. A memory access command 322-0 includes a row access command 324 and a two-column burst command 326. The bank corresponding to the row specified by the row access command 324 is not automatically pre-charged at the end of the operation specified by the command 322-0, allowing subsequent two-column burst commands 322-1 through 322-7 to be executed for the specified row. The timing diagram 320 thus illustrates a burst length corresponding to eight memory access commands 322-0 through 322-7. In some embodiments, the commands 322-1 through 322-7 are issued in single cycles (e.g., 328); no commands are issued during the cycles that otherwise would include row commands (e.g., a NOP is issued). In some embodiments, two-column burst commands are generated in the corresponding memory device in response to an initial command received from the memory controller; a counter in the device controls the burst length. Upon completion of the two-column burst commands 322-1 through 322-7, a memory access command 322-8 specifies a new row and pair of columns, and is followed by two-column burst commands 322-9, 322-A, and 322-B directed to additional pairs of columns in the new row. DQ signal 307 illustrates the data words output in response to the memory access commands 322: data word 330-0 is output in response to command 322-0, data word 330-1 is output in response to command 322-1, and so forth. The data words are provided to the memory controller 102 via the data path 108 for the device to which the commands 322 are directed (e.g., data path 108a for device 106a). For visual clarity, the latency 332 associated with the commands 322 is shown as sixteen (16) cycles; this value is merely an example and may vary. For example, the latency 332 may be 48 cycles, as shown for latency 312 in FIG. 3A.

Performing multiple column access commands (e.g., multiple two-column burst commands) for a given row reduces row operation power compared to performing successive memory access commands that specify distinct row addresses.

In the examples of FIGS. 3A and 3B, memory access commands 304 or 322 are provided via a control path to each memory device on a module but are directed to and executed by a single device. Other devices on the module disregard the commands. In these examples, the memory device to which the commands are directed continuously outputs data. The control path has unused bandwidth, however, because commands are only issued to the memory device every sixteen (16) cycles. Thus, assuming two-cycle commands, there are 14 unused cycles on the control path between successive commands. These unused cycles may be used to direct other memory access commands to other memory devices on the module. In some embodiments, memory access commands issued to a particular memory device on the module are independent of commands issued to other devices. Furthermore, in systems in which multiple modules (e.g., 104-1 and 104-2) are coupled to the controller by independent control paths (e.g., CA0 112-1 and CA1 112-2), separate and independent memory access commands may be simultaneously directed to memory devices on separate modules.

FIG. 3C illustrates a timing diagram 340 for memory access commands directed to successive memory devices in accordance with some embodiments. The timing diagram 340 corresponds to memory system 100 (FIG. 1A) and includes clock signals CK0 302 and CK1 342 provided to modules 104-1 and 104-2 respectively. Memory access command signals CA0 305 and CA1 344 are provided to modules 104-1 and 104-2 respectively via control paths 112-1 and 112-2. DQ signals 307 correspond to data transferred between memory devices 106 and the controller 102 via data paths 108. For example, DQ signal 307c corresponds to data transferred between memory device 106c and the controller 102 via data path 108c.

Signal CA0 305 includes a contiguous sequence 346 of memory access commands provided to memory devices 106 on the first module 104-1 and directed in turn to successive memory devices 106 in a repeating fashion. For example, a first command is directed to device 106a, a second command is directed to device 106c, and so on until a command has been directed to device 106o, after which another command is directed to device 106a, and the sequence repeats with new commands. Simultaneously, signal CA1 344 includes a contiguous sequence 348 of memory access commands provided to memory devices 106 on the second module 104-2 and directed in turn to successive memory devices 106 in a repeating fashion. The commands in the sequence 348 are independent of the commands in the sequence 346. For example, during a particular clock cycle a first command may be directed to a first address in device 106a on module 104-1 and a second command may be directed to a second address in device 106b on module 104-2, wherein the first address is independent of the second address.

The sequences of commands 346 and 348 use the full bandwidth of the control paths 112 while allowing each device 106 to output data continuously in the absence of bank interference.

If a first memory access command directed to a particular device is followed a period t_{RR} 310 later by a subsequent command directed to the particular device and specifying an address in the same bank as the first command, bank interference occurs and the device will not be able to respond to the subsequent command within a period 332 equal to t_{RR} 310, resulting in an interruption in its otherwise continuous output. This scenario is illustrated in a timing diagram 360 in FIG. 3D in accordance with some embodiments. In the timing diagram 360, a sequence of commands 362 includes successive commands 364 and 366 directed to memory device 106a and specifying addresses in the same bank. As a result, the DQa signal 307a is interrupted: an idle period 368 exists between data word 350a-0, corresponding to command 364, and data word 350a-1, corresponding to command 366. In some embodiments, a memory controller will not issue successive memory access commands 364 and 366 directed to the same bank of a particular device. For example, the memory controller will issue successive memory access commands (e.g., commands separated by a period t_{RR} 310) to a particular device that are directed to successive banks in the device in a round-robin fashion. If no memory access command directed to a particular bank is queued in the controller, a NOP instruction is provided to the device in the corresponding command signal timeslot, resulting in an idle period between output data words for the device. Alternatively, if no memory access command directed to a particular bank is available for the corresponding timeslot, the memory controller may dynamically adjust queued memory access commands and issue a memory access command that is directed to another bank and that does not result in bank interference with previously issued commands.

Because each command in the sequence 362 is directed to a particular device on the module 104-1 and is independent of other commands, the idle period 368 between data words 350a-0 and 350a-1 only affects the DQa signal 307a for device 106a. The other devices 106 on the module 104-1 are not affected: no interruption is seen, for example, in signals DQc 307c and DQo 307o, which correspond to devices 106c and 106o. Furthermore, because the commands in the sequence 348 are independent of the commands in the sequence 362, the devices on the second module 104-2 also are not affected. Bank interference thus is substantially reduced compared to architectures in which memory commands are directed to multiple devices in parallel. Directing each command to a particular device on a module instead of in parallel to all devices on a module also reduces transfer granularity, thus improving performance.

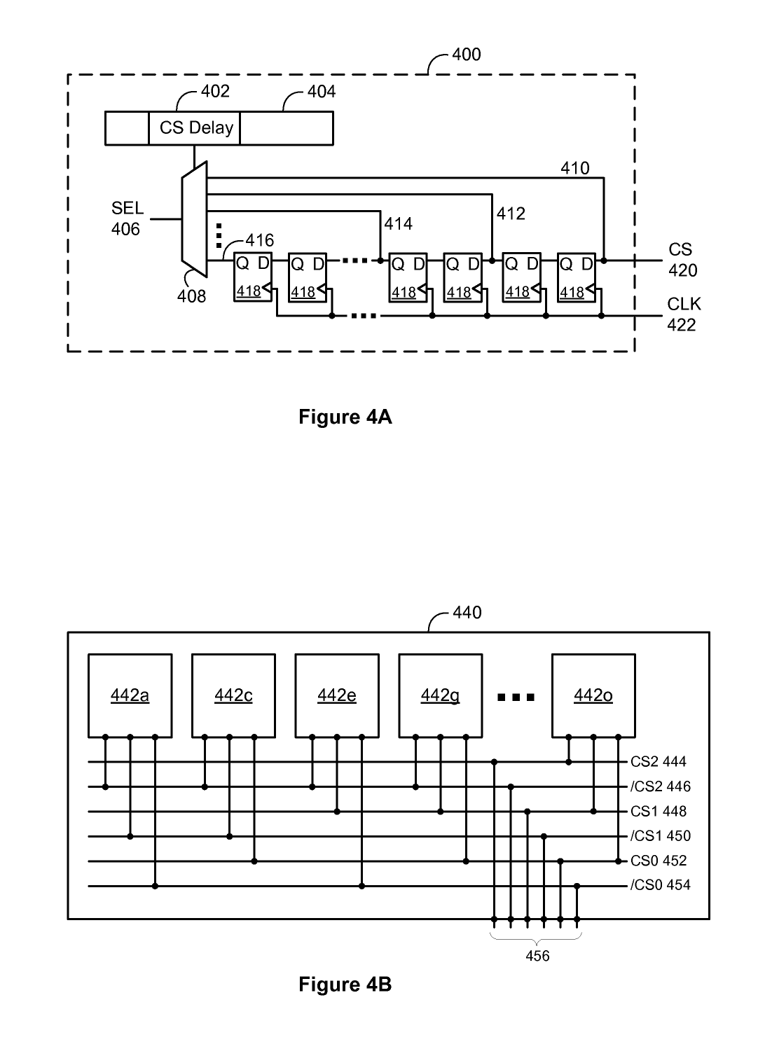

Various design options allow a particular memory device to determine whether a received memory access command is directed to the device, and thus whether to perform the memory access command. FIG. 4A is a schematic diagram of variable-delay chip select (CS) circuitry 400, which may also be called a variable-delay buffer, in a memory device (e.g., 106 or 142) in accordance with some embodiments. A CS delay value 402 is stored in a configuration register 404. For example, the microcontroller 102 writes the CS delay value 402 to the configuration register 404 during initialization. In some embodiments, each memory device on a module has a unique CS delay value 402. For example, memory device 106a on module 104-1 is assigned a CS delay value 402 of 0, memory device 106c is assigned a CS delay value 402 of 1, and so on, such that memory device 106o is assigned a CS delay value of 7. A CS signal 420 received in parallel by the memory devices on the module (e.g., via control path CA0 112-1 for module 104-1) is provided to a series of daisy-chained flip-flops 418. The flip-flops 418 are clocked by a clock signal 422, such as CK0 302, CK1 342, or a locally-generated clock signal with a frequency equal to the frequency of CK0 302 or CK1 342. Signal lines (e.g., 410, 412, 414, and 416) provide the output of successive pairs of flip-flops 418 as input to a multiplexer (mux) 408. The CS delay value 402 provides a control signal 405 to the mux 408 to select a particular input. For example, if the CS delay value 402 is 0, the mux selects signal line 410 as its output; if the CS delay value 402 is 1, signal line 412 is selected; and if the CS delay value 402 is 2, signal line 414 is selected. If the CS delay value equals the total number of memory devices on the module minus one (e.g., equals seven for module 104-1), signal line 416 is selected. The output of the mux 408 is a SEL signal 406 that when asserted (e.g., is high) enables the memory device to execute a received memory access command and when de-asserted (e.g., is low) causes the memory device to disregard received memory access commands. The variable delay CS circuitry 400 thus provides a programmable CS delay in increments of two clock cycles. Similar variable delay CS circuitry may be designed with other delay increments.

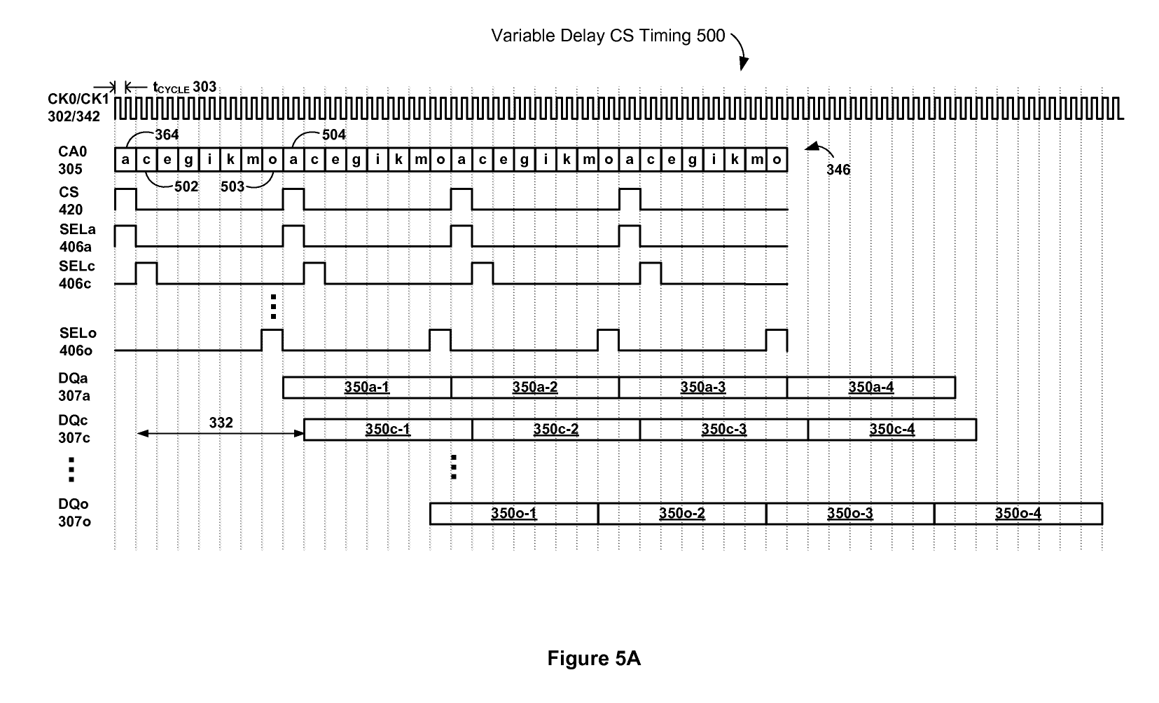

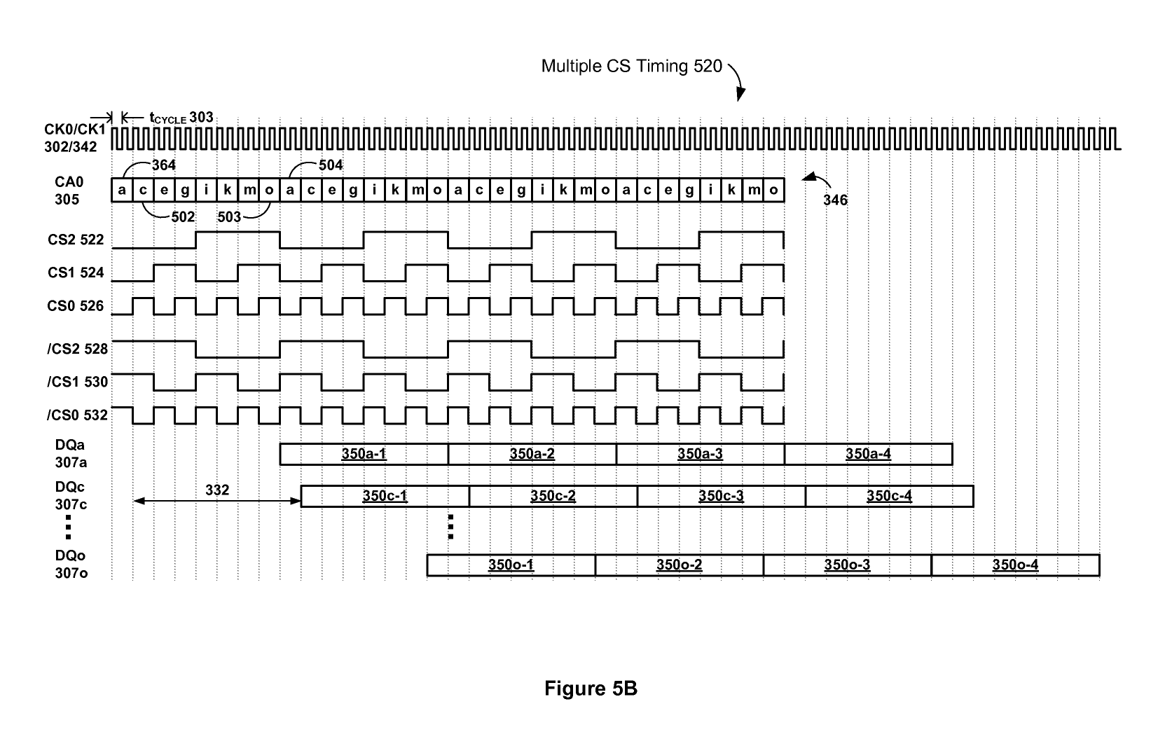

Assigning a distinct CS delay value 402 to each memory device on a respective module and asserting the CS signal 420 once at the beginning of a series of memory access commands directed successively to each memory device enables each memory device to perform a distinct memory access command and to disregard the remaining commands in the series. The timing 500 associated with this configuration is illustrated in FIG. 5A in accordance with some embodiments. The sequence of memory access commands includes a series of eight commands 364 through 503. The CS signal 420 is asserted (pulsed high) for two cycles corresponding to command 364. Because memory device 106a has a delay value 402 equal to zero, the SEL signal in device 106a (i.e., SELa 406a) is asserted in parallel with command 364, enabling device 106a to perform command 364. The SEL signals in the remaining devices (i.e., SELc 406c through SELo 406o) remain low: those devices have non-zero delay values 402 and disregard command 364. Device 106c has a delay value 402 of one, causing SELc 406c to be asserted in parallel with the next command, command 502, and enabling device 106c to perform command 502. For each subsequent command, a SEL signal 406 is asserted in a single device 106, enabling that device 106 to perform the command, until a series of new commands begins with command 504.

Signals CS 420 and SEL 406 have been shown and described as being high when asserted. Alternately, these signals may use active-low logic such that they are low when asserted.

In some embodiments, a module may be operated in multiple modes by varying the CS delay values 402 for the memory devices on the module. In a first mode, each memory device is assigned a distinct CS delay value 402. In a second mode, multiple memory devices are assigned identical CS delay values 402. For example, each memory device may be assigned an identical CS delay value 402, thereby allowing each memory device to process a command received when SEL 406 is active in each device.

In some embodiments, instead of using variable delay circuitry, the control path (e.g., CA0 112-1 or CA1 112-2) includes multiple CS signal lines, including a set of true CS signal lines and a corresponding set of complement signal lines, as illustrated for a memory module 440 in FIG. 4B in accordance with some embodiments. Memory module 440 represents a possible implementation of module 104. Edge contacts 456 on the module 440 couple the CS signal lines to a control path on a printed circuit board, and thereby to a memory controller. The number of signal lines in each set (true or complement) is sufficient to address uniquely each memory device on the module. For example, if the module 440 has eight memory devices 442 (i.e., 442a through 442o), there are three true signal lines (CS2 444, CS1 448, and CS0 452) and three complement signal lines (/CS2 446, /CS1 460, and /CS0 454). Each memory device 442 is coupled to a distinct sub-set of the CS signal lines. When all of the CS signals on the signal lines in a distinct subset are asserted (e.g., are high), the corresponding memory device 442 is selected and will execute a received memory access command. When one or more CS signals on the signal lines in a subset is de-asserted (e.g., is low), the corresponding memory device 442 is de-selected and will disregard received memory access commands.

To determine the distinct subset of CS signal lines to couple to each memory device 442, each memory device is assigned a distinct binary number. For example, device 442a=[000], device 442c=[001], device 442e=[010], and so forth, such that device 442o=[111]. If the most significant bit of the device's assigned number is 0, the device 442 is connected to /CS2 446; if the most significant bit is 1, the device 442 is connected to CS2 444. If the intermediate bit of the device's assigned number is 0, the device 442 is connected to /CS1 450; if the intermediate bit is 1, the device 442 is connected to CS1 448. If the least significant bit of the device's assigned number is 0, the device 442 is connected to /CS0 454; if the least significant bit is 1, the device 442 is connected to CS0 452.

For a sequence of eight memory access commands directed successively to memory devices 442a through 442o, the value of [CS2,CS1,CS0] on the true signal lines is incremented for each successive memory access command, such that the value counts from to [111] and the value on the complement signal lines varies accordingly. This timing 520 is illustrated in FIG. 5B in accordance with some embodiments. For each memory access command, only one device 442 will receive signals on its subset of CS signal lines that are all asserted (e.g., are all high). That device will perform the corresponding memory access command; the remaining memory devices will disregard the command. For example, when memory access commands 364 and 504 are provided to the devices, signals /CS2 528, /CS1 530, and /CS0 532 are asserted. Since only device 442a is coupled to the corresponding signal lines 446, 450, and 454, only device 442a performs the commands 364 and 504. Similarly, only device 442c performs command 502 and only device 442o performs command 503.

In some embodiments, incrementing the value of [CS2,CS1,CS0] for each successive memory access command corresponds to a first mode of operation. In a second mode of operation, all of the CS signals 444, 446, 448, 450, 452, and 454 are simultaneously asserted to enable all of the memory devices 442a through 442o to process commands in parallel. In this context, “in parallel” means during substantially overlapping time periods. In one embodiment, in response to a read command, while operating in the second mode, data is provided on parallel data paths 108 (FIGS. 1A, 1B) by all of the memory devices of a memory module 104 during an identical set of clock cycles.

In some other embodiments, each device on a module is connected to a set of multiple CS signal lines, all of which are true CS signal lines. Each device has a distinct device ID stored in a configuration register. For example, the controller 102 writes a distinct device ID to each device during initialization. If a device's ID equals the value of the bits on the CS signal lines, the device is selected and is able to perform memory access commands; otherwise the device is deselected and will disregard memory access commands. Alternately, device ID may be specified in memory access command opcodes.

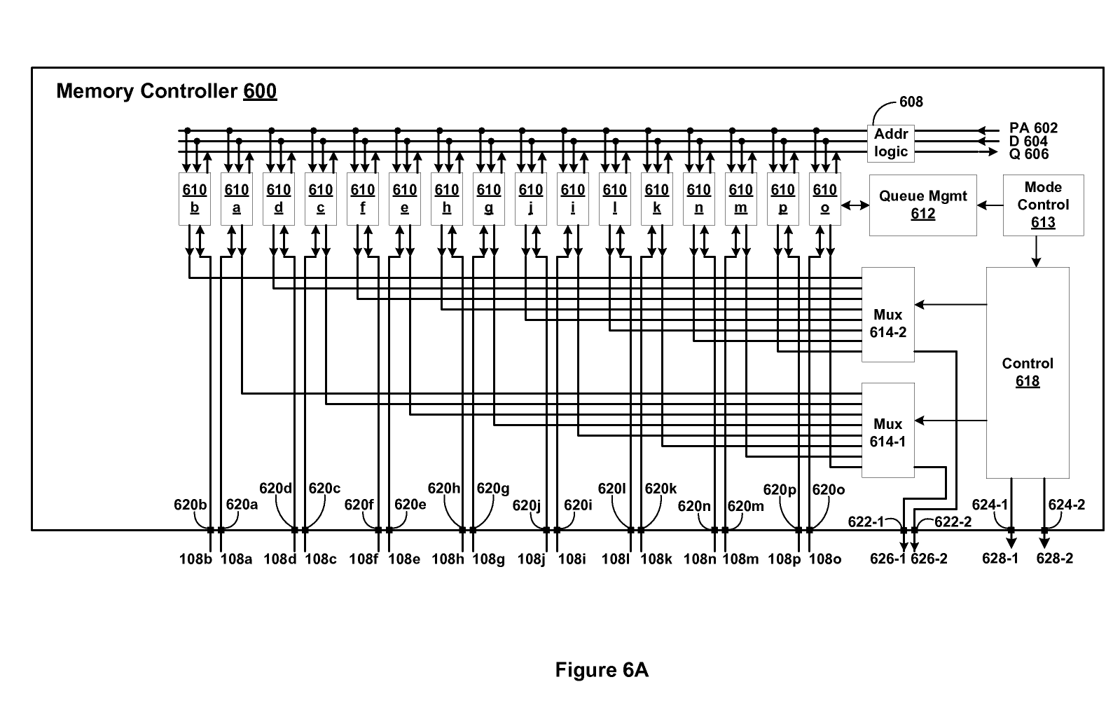

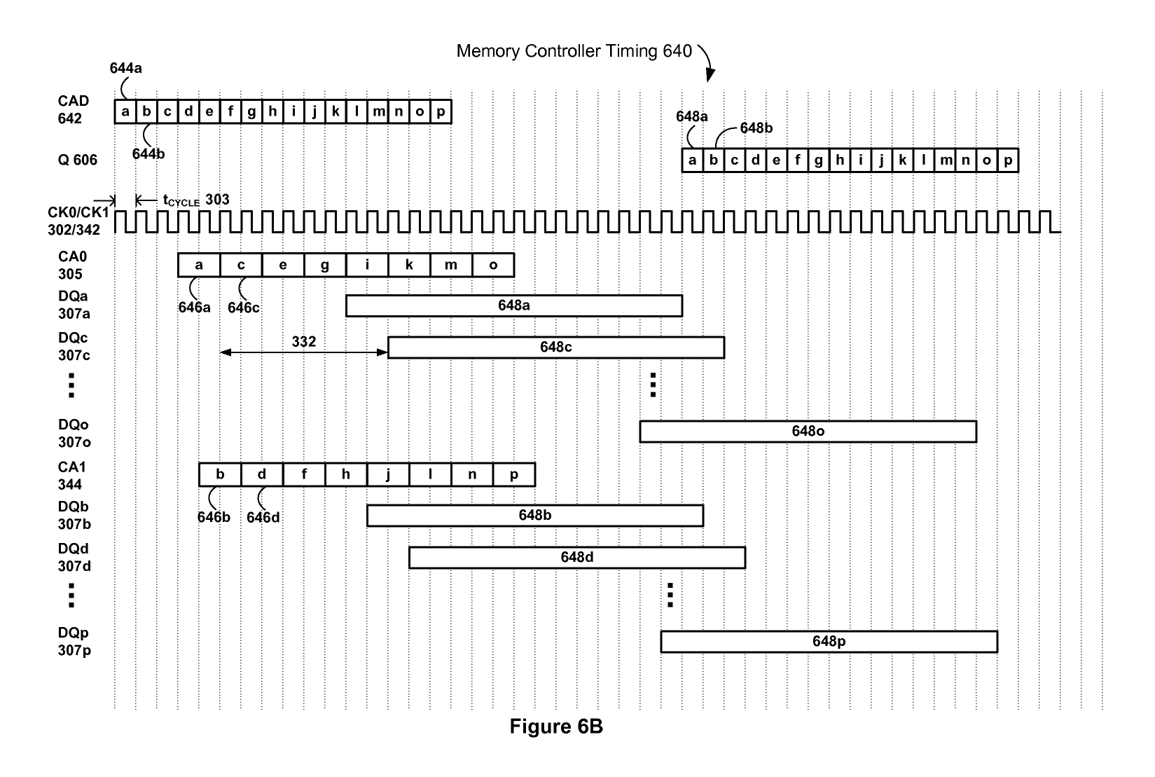

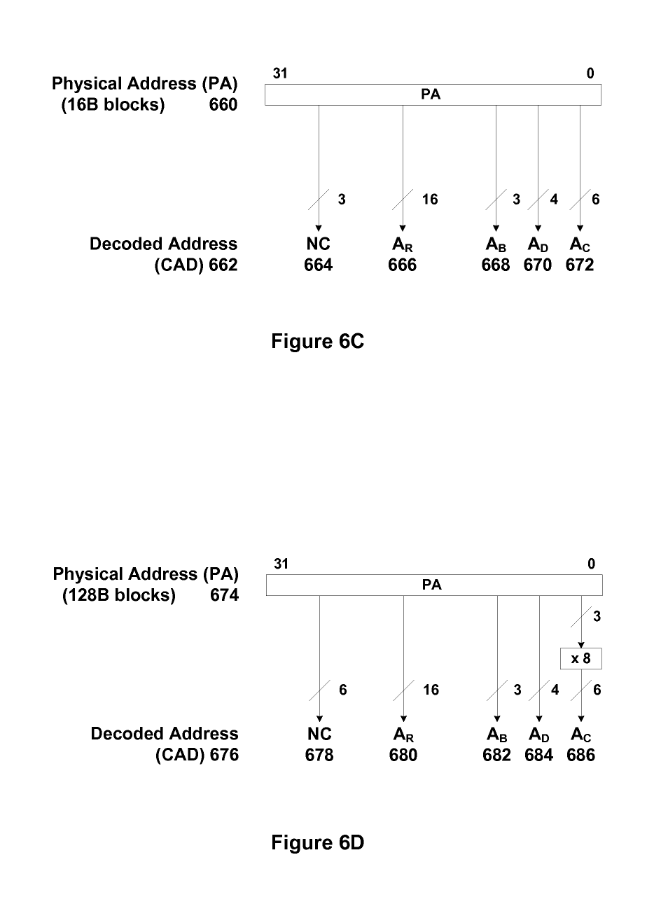

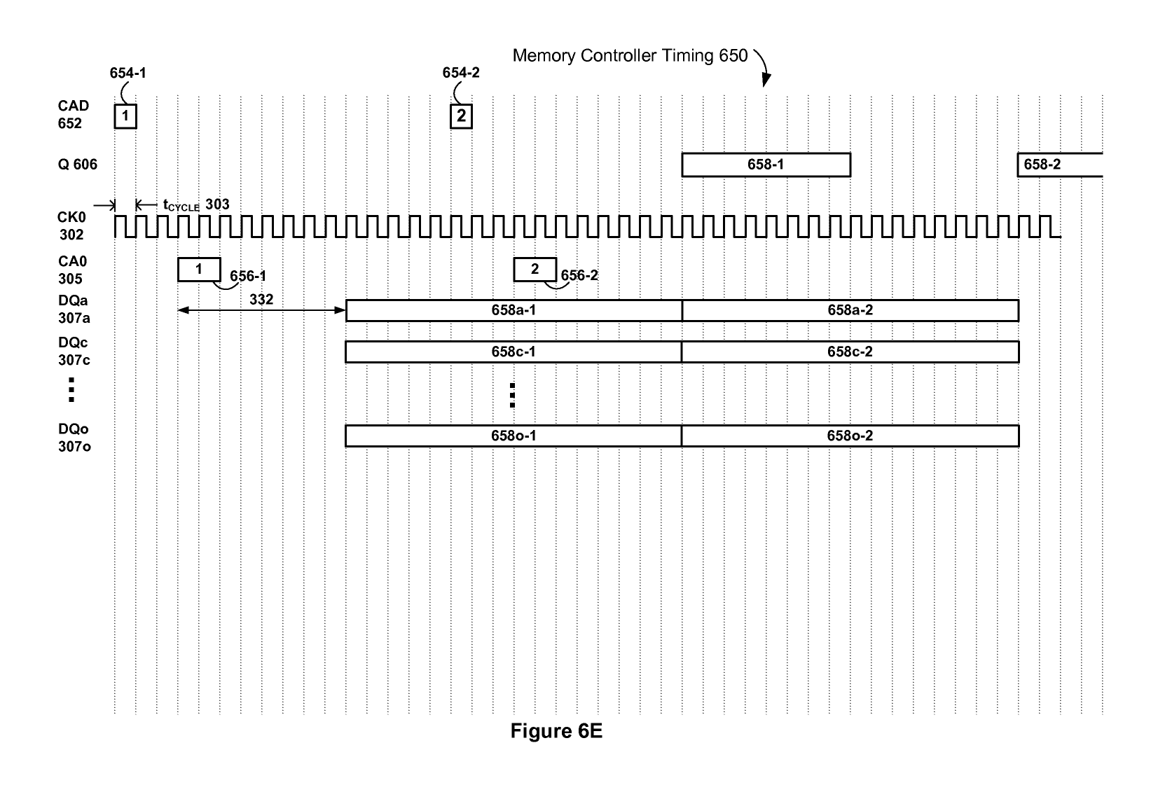

Attention is now directed to an example of an architecture for the memory controller 102. FIG. 6A is a block diagram of a portion of a memory controller 600 in accordance with some embodiments. A physical address 602 is provided to address decode logic 608, which decodes the physical address to a decoded address (“CAD”) (i.e., an electrical address) to be provided to a memory device coupled to the controller 600. The decoded address, which specifies a location in the memory device for memory access or write commands, is directed to a queue 610 corresponding to the memory device. Data 604 to be written to the memory device also is directed to the corresponding queue 610. In some embodiments, data 604 is 128 bits wide. The queues 610 queue the decoded addresses and data. The sixteen (16) queues in memory controller 600 may correspond to sixteen (16) memory devices, such as the eight devices of module 104-1 and the eight devices of module 104-2. For example, queue 610a corresponds to memory device 106a and queue 610b corresponds to memory device 102b.

Data 606 received from the memory devices is queued in the queues 610 and then transferred to other circuitry (not shown) for processing. For example, the data 606 is transferred to a transmitter in the memory controller 600 that transmits the data 606 to a microprocessor. In some embodiments, data 606 is 128 bits wide and corresponds to a two-column data burst from a memory device.

In some embodiments, each queue 610 includes multiple sub-queues, such as a sub-queue for memory access (i.e., read) commands to be directed to a corresponding memory device, a sub-queue for write commands to be directed to the corresponding memory device, and a sub-queue for data received from the corresponding memory device in response to memory access commands. In some embodiments, sub-queues for memory access commands or for write commands store commands to be issued to corresponding memory devices as well as decoded addresses. In addition, sub-queues for write commands store data to be written to corresponding memory devices.

The decoded address at the front of a queue 610 (e.g., at the front of a sub-queue for memory access commands or for write commands) is provided to a scheduling circuit, which in some embodiments includes a mux 614 The mux 614 selects decoded addresses for transmission to memory devices via an address interface 622. In some embodiments a first mux 614-1 and corresponding first address interface 622-1 transmit decoded addresses to a first module (e.g., 104-1 or 144-1) and a second mux 614-2 and corresponding second address interface 622-2 transmit decoded addresses to a second module (e.g., 104-2 or 144-2). Control circuitry 618 controls the muxes 614. In some embodiments, the control circuitry 618 directs the muxes 614 to multiplex the decoded addresses in a round-robin manner, as in command sequences 346 and 348 (FIG. 3C).

Data at the front of a queue 610 (e.g., at the front of a sub-queue for write commands) is transmitted to memory devices via data path interfaces 620. The signal lines to which the data path interfaces 620 are coupled correspond to data paths 108. For example, in memory system 100 (FIG. 1A), data path interface 620c is coupled to data path 108c and thus to memory device 106c.

In some embodiments, two queues correspond to a single memory device. For example, queues 610a and 610c may correspond to device 142ac (FIG. 1C) and are coupled to device 142ac through data paths 108a and 108c. In another example, queues 610a and 610b may correspond to device 106a in memory system 120 (FIG. 1B), with device 106a configured in ×8 mode. In this example, queue 610a is coupled to device 106a through data path 108a and queue 610b is coupled to device 106a through the combination of data paths 108b, 124b, and 110a. Therefore, this implementation of memory system 120 uses two sets of queues and two corresponding sets of data path interfaces to transmit and receive data to and from devices on the module 104-1. The first set of data path interfaces is coupled directly to the module 104-1 via data paths 108a, 108c, etc. (FIG. 1B), and the second set of data interfaces is coupled to the module 104-1 via data paths 108b, 108d, etc. and the continuity module 122.

The control circuitry 618 provides CS signals to a first control interface 624-1 for transmission to the first module and to a second control interface 624-2 for transmission to the second module. Examples of CS signals are shown in FIGS. 5A and 5B. In the example of FIG. 5A, in which CS 420 is pulsed high for a command 364 to a first device 106a and then is low for the next seven commands, the corresponding mux 614 delays transmission of an address with respect to transmission of the CS signal by a number of clock cycles specific to the respective memory device to which the address is directed. For example, if device 106c has a CS delay value 402 equal to one, the mux 614-1 delays transmission of an address to the device 106c by two clock cycles with respect to the CS signal. Therefore, in some embodiments, the number of clock cycles by which an address is delayed corresponds to a delay for the CS signal in the memory to which the address is directed.

In some embodiments the controller 600 transmits to the memory devices on a module one or more sequences of read commands successively directed (e.g., in round robin order) to each device on the module, followed by one or more sequences of write commands successively directed to each device on the module. In some embodiments each sequence includes commands and addresses transmitted from respective queues 610 and directed in turn to each respective memory device on the module in a round-robin fashion. Sequences of write commands also include data to be written respectively to each device. Performing full sequences of read commands followed by full sequences of write commands limits overhead associated with turning around the data paths 108. In some embodiments, commands directed to a particular device in successive sequences are directed to respective banks within the particular device in a round-robin fashion. If no command is available for a particular device or bank during a corresponding timeslot, a NOP may be performed instead. Alternatively, a command for a different device or bank may be performed by dynamically reordering the queue 610, assuming that the CS signal for the different device can be varied accordingly and that bank interference can be avoided.

The combination of signal lines 626 and 628 to which the control interfaces 624 and address interfaces 622 are coupled correspond to control paths. The combination of control interface 624-1 and address interface 622-1 constitutes a first control path interface (e.g., CA0 112-1, FIGS. 1A, 1B, 1C). The combination of control interface 624-2 and address interface 622-2 constitutes a second control path interface (e.g., for control path CA1 112-2, FIGS. 1A, 1B, 1C). Control paths may include additional signals (not shown).

In some embodiments, the memory controller 600 includes queue management logic 612 coupled to queues 610. (For visual clarity, the queue management logic 612 is shown as coupled to queue 610o; in practice, the logic 612 may be coupled to multiple queues 610 or to every queue 610.) The queue management logic 612 examines the queues 610 and attempts to reorder the queues 610 to reduce or minimize bank interference by sorting respective queues 610 according to the bank addresses of entries in the respective queues 610. For example, queue entries corresponding to commands are reordered by their bank addresses to enable commands for a particular device to be directed to successive banks in a round robin fashion. Both queue entries to be transmitted to a memory device and queue entries received from a memory device may be reordered. By allowing commands to be issued to memory devices in a different order than the order in which the controller 600 places addresses and/or data in the queues 610, the queues 610 and queue management logic 612 enable out-of-order (OOO) processing.

FIG. 6B illustrates a timing diagram 640 for the memory controller 600 in accordance with some embodiments. A clock signal CK0 302/CK1 342 has a period 303 and a corresponding frequency. In some embodiments, the period 303 is 0.625 ns or less, corresponding to frequency of 1.6 GHz or higher. A sequence of decoded addresses 642 is provided to queues 610. For example, address 644a is provided to queue 610a and address 644b is provided to queue 610b. The addresses are transmitted via address interfaces 622 to memory devices as part of control signals CA0 305 and CA1 344. The control signals CA0 305 and CA1 344 include a sequence of memory access commands 646, such that address 644a is specified in command 646a, address 644b is specified in command 646b, and so forth. In some embodiments, a command 646 includes a row access command and a two-column burst command.

In response to the memory access commands 646, data words 648 are received from the memory devices at data path interfaces 620 (FIG. 6A). For example, in response to command 646a, data word 648a is received at data path interface 620a; in response to command 646b, data word 648b is received at data path interface 620b. The received data words 648 are queued in corresponding queues 610 (FIG. 6A) and are transferred as data signal 606. For example, received data word 648a is queued in queue 610a and received data word 648b is queued in queue 610b. In some embodiments, data signal 606 is sufficiently wide (e.g., ×128) to allow each data word 648 to be transferred in a single cycle. In some embodiments, the data words 648 in the data signal 606 are transmitted by the memory controller 600 to a microprocessor for processing.

FIGS. 6C and 6D illustrate address decoding performed by the address decode logic 608 in accordance with some embodiments. In these examples, a decoded address (CAD) includes a device address A_{D} specifying a memory device and bank, row, and column addresses A_{B}, A_{R}, and A_{C} specifying a bank, row, and column in the specified memory device. In FIG. 6C, a 32-bit physical address (PA) 660 that points to a 128-bit (16-byte, also written as 16B) block in memory space is decoded into a decoded address (CAD) 662. The three most significant bits (MSBs) in the PA 660 are not used (NC 664). The next sixteen (16) MSBs correspond to a row address A_{R} 666, the following 3 bits correspond to a bank address A_{B} 668, the following 4 bits correspond to a device address A_{D} 670, and the 6 least significant bits (LSBs) correspond to a column address A_{C} 672.

In FIG. 6D, 32-bit PA 674 points to a 128-byte (128B) block in memory space and is decoded into CAD 676. The six most significant bits (MSBs) in the PA 674 are not used (NC 678), the next sixteen (16) MSBs correspond to a row address A_{R} 680, the following 3 bits correspond to a bank address A_{B} 682, and the following 4 bits correspond to a device address A_{D} 684. The 3 LSBs are multiplied by eight (i.e., three zeros are appended) to generate a 6-bit wide column address A_{C} 686. The three LSBs of A_{C} 686 may be incremented by the memory controller (e.g., by address decode logic 608) or by the memory device, for example in response to multiple-column burst commands received from the memory controller.

The device address A_{D} (e.g., 670 or 684) determines the queue 610 to which a decoded address (e.g., 662 or 676) is provided. The queue 610 stores the bank address A_{B} (e.g., 668 or 682), row address A_{R} (e.g., 666 or 680), and column address A_{C} (e.g., 672 or 686) of the decoded address and provides these addresses to the corresponding memory device through an address interface 622.

In some embodiments a controller 600 is configurable to enable multiple modes of operation. FIG. 6B illustrates a first mode of operation. In a second mode of operation, instead of directing independent addresses to respective memory devices, a single address for a single command is directed to each memory device in parallel (i.e., to all of the memory devices on a module in parallel), and each memory device is configured to process the command. In this second mode, data is received from each memory device (i.e., from every memory device on the module, in parallel) in response to each memory access command. This second mode may be implemented, for example, by suspending round-robin operation of the muxes 614 and storing addresses to be issued to a particular module for successive memory access commands in a queue 610 coupled to an address interface 622 through a mux 614. In some embodiments, mode control logic 613 selects a particular mode of operation. In some embodiments the mode control logic 613 includes one or more registers to store values specifying the mode of operation.

FIG. 6E illustrates a timing diagram 650 for the second mode of operation in accordance with some embodiments. A sequence of decoded addresses 652, including a first address 654-1 and a second address 654-2, is provided to a queue 610. Because the addresses 654 are to be provided in parallel to each memory device on a module, the addresses 654 do not include device addresses. Alternately, device addresses in the addresses 654 are ignored. The addresses 654-1 and 654-2 are transmitted to the memory devices via an address interface 622 as part of memory access commands 656-1 and 656-2, which are included in the control signal CA0 305. In response to the memory access commands 656-1 and 656-2, data words 658 are received in parallel from the memory devices at data path interfaces 620. The received data words 658 are stored in queues 610 and then transferred as data signal 606.

In some embodiments memory devices are configured to output shorter data words in response to memory access commands in the second mode than in the first mode. The frequency of memory access commands 656 may be increased in accordance with the decrease in the length of output data words 658.

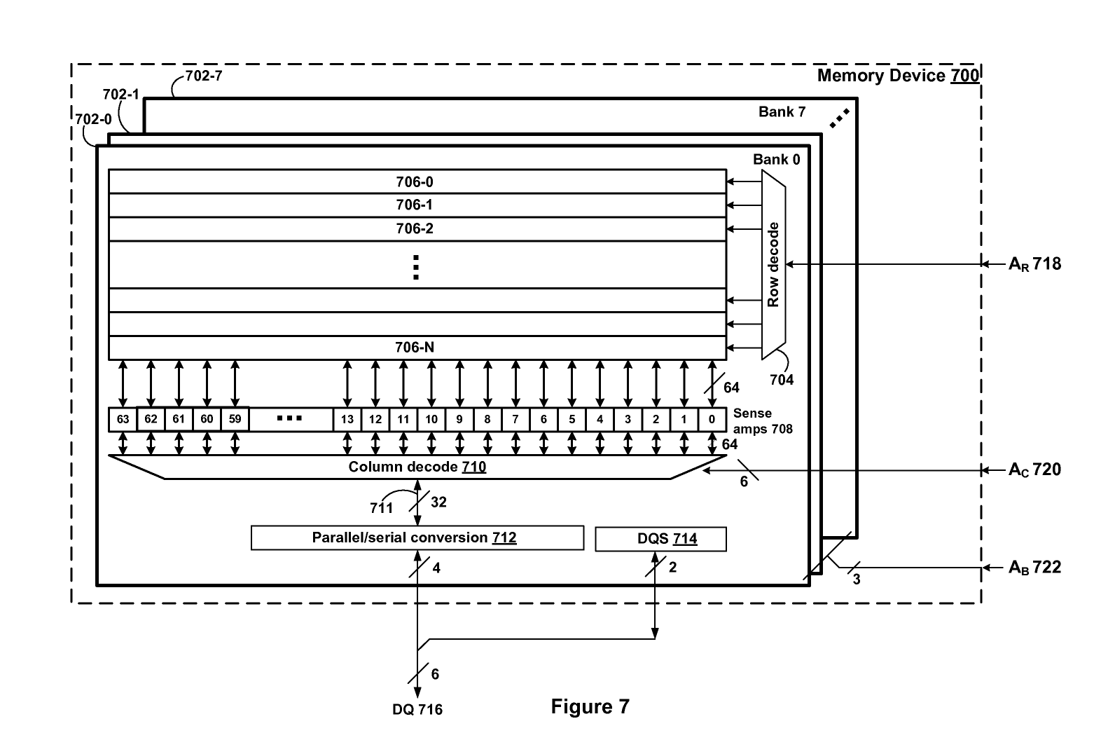

FIG. 7 is a block diagram of a portion of a memory device 700 in accordance with some embodiments. FIG. 7 provides an example of how decoded addresses such as CAD 662 (FIG. 6C) or 676 (FIG. 6D) correspond to memory device architecture. Memory device 700 is a possible implementation of memory device 106. In some embodiments, memory device 700 is a DRAM. The number of banks, rows, and columns in memory device 700 may vary in practice, as may the column width and bus widths. A bank address A_{B} 722 provided to memory device 700 selects one of eight banks 702. Each bank 702 includes rows 706-0 through 706-N. A row address A_{R} 718 is provided to row decode logic 704, which selects a particular row 706. The width of A_{R} 718 corresponds to the depth (i.e., the number of rows 706) of the bank 702. In the examples of FIGS. 6C and 6D, the row addresses 666 and 680 are sixteen (16) bits wide, corresponding to a bank depth of 64K rows. In another example, the row address is fourteen (14) bits wide, corresponding to a bank depth of 16K rows.

The columns in each bank are coupled to corresponding sense amplifiers (“sense amps”) 708. The memory device 700 is shown with 64 columns and 64 accompanying sets of sense amps 708, with each column being 64 bits wide. Column decode logic 710 receives a column address A_{C} 720 and couples the sense amps 708 corresponding to the column specified by A_{C} 720 to parallel/serial conversion circuitry 712. In some embodiments, the bus 711 coupling the column decode logic 710 to the parallel/serial conversion circuitry 712 is half as wide as the column (e.g., ×32 for ×64 columns), such that data detected by the sense amps 708 for a column specified in a memory access command is transferred to the parallel/serial conversion circuitry 712 in two cycles. The parallel/serial conversion circuitry 712 is coupled to a data bus 716 and sends or receives data in four-bit increments. In some embodiments, the data bus 716 is configured for double-data rate (DDR) transmission and transmits or receives eight data bits per cycle. Strobe circuitry 714 sends or receives two strobes in parallel; each strobe times the transmission of data on two signal lines of the data bus 716. In some embodiments the width of the data bus 716 is configurable, such that the data bus 716 has a first width (e.g. ×4 for memory devices 106 in FIG. 1A) in one mode and a second width (e.g. ×8 for memory devices 106 in FIG. 1B) in another mode. In some embodiments the width of the data bus 716 is specified by writing a value to a configuration register (not shown) in the device 700.

In some embodiments, error-correction coding (ECC) syndromes are associated with data stored in memory devices on a module. For example, a 16-byte ECC syndrome is associated with 128 bytes of data. The ECC syndromes may be stored in the same memory device as their corresponding data. Each memory device on a module may store ECC syndromes associated with stored data, or a subset of memory devices on a module may store ECC syndromes associated with stored data. Alternately, ECC syndromes may be stored in a separate dedicated memory device on the module.

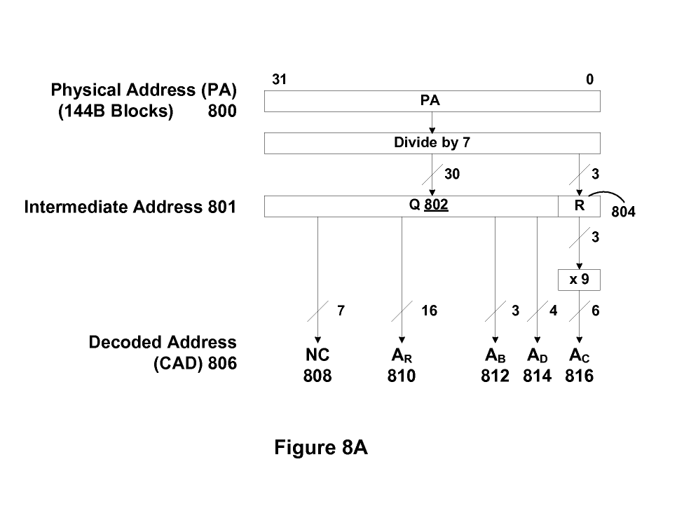

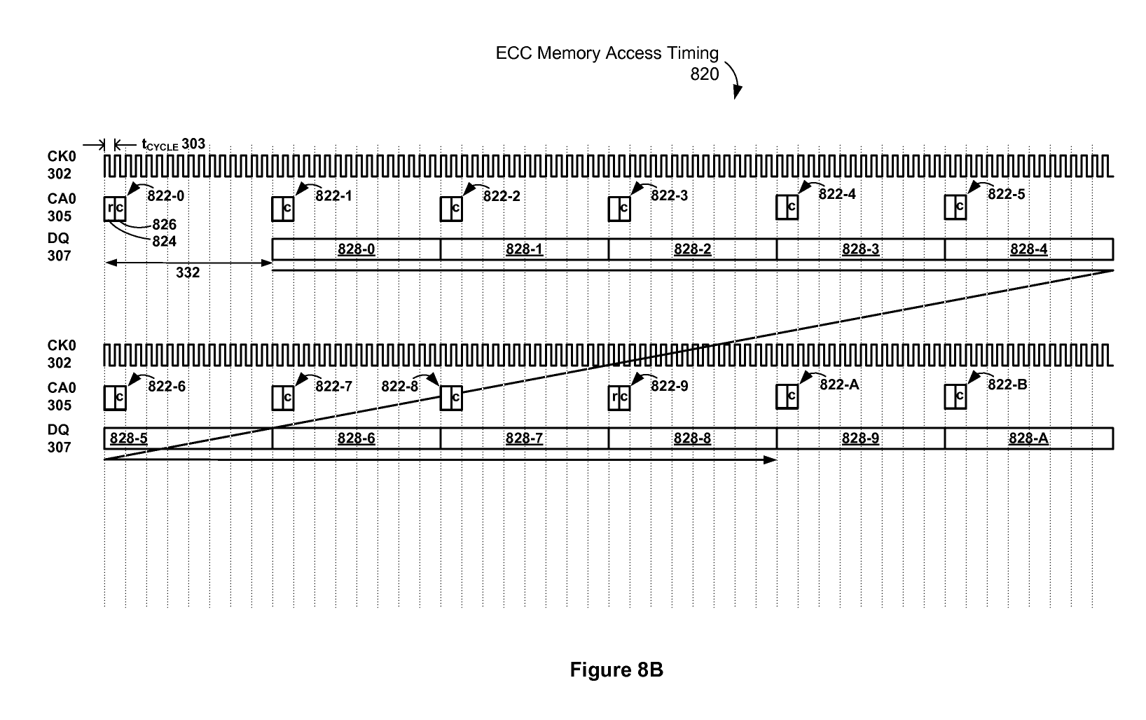

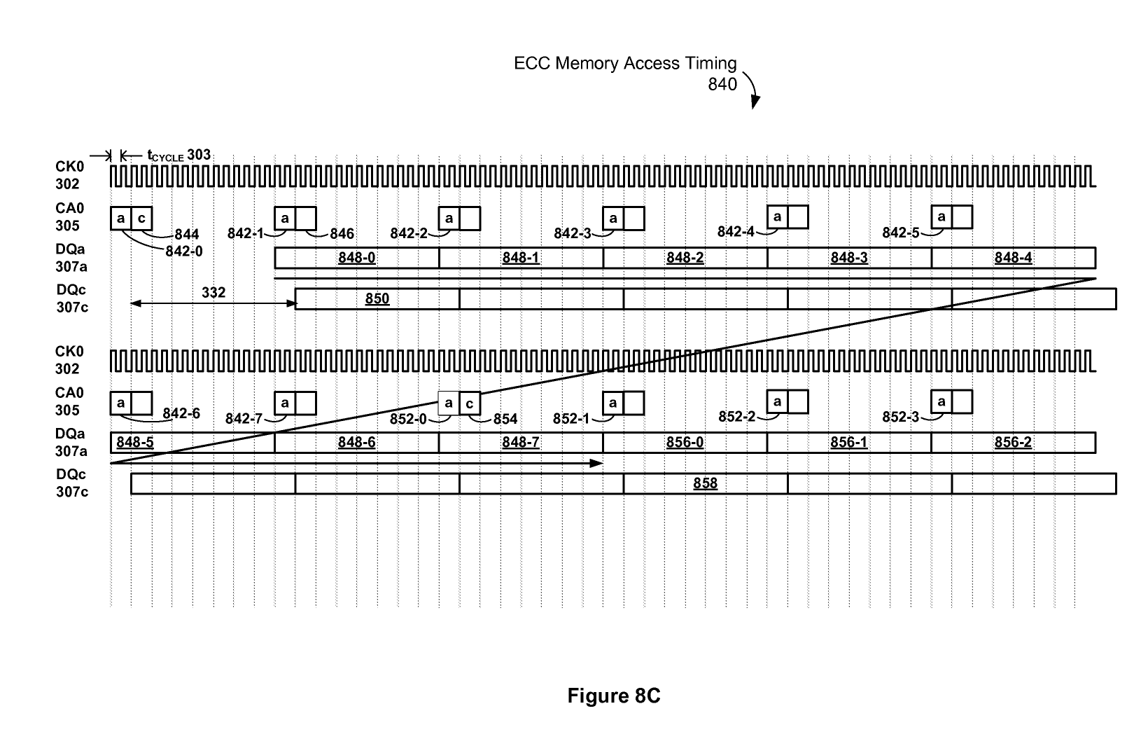

For memory devices that store ECC syndromes along with corresponding data, physical addresses must be decoded to allow for storing the ECC syndromes. For example, each 512B row in the memory device 700 is divided into seven 72B (seventy-two byte) blocks. FIG. 8A illustrates address decoding for memory with 72B blocks that include 8B of ECC syndromes in accordance with some embodiments. In some embodiments, the address decoding shown in FIG. 8A is performed by address decode logic 608 (FIG. 6A). A 32-bit physical address (PA) 800 that points to a 72B block in memory space is decoded into a decoded address (CAD) 806. First, PA 800 is divided by seven, resulting in a 30-bit quotient 802 and a 3-bit remainder 804. The seven most significant bits (MSBs) in the quotient 802 are not used (NC 808). The next sixteen (16) MSBs correspond to a row address A_{R} 810, the following 3 bits correspond to a bank address A_{B} 812, and the following 4 bits correspond to a device address A_{D} 814. The 3-bit remainder 804, which has possible values of zero to six, is multiplied by nine to generate a 6-bit wide column address A_{C} 816 with seven possible values (0, 9, 18, 27, 36, 45, or 54). Each of the seven possible values of A_{C} 816 corresponds to a group of nine columns in the memory array: for example, an A_{C} 816 value of 0 corresponds to columns 0-8 and an A_{c} 816 value of 36 corresponds to columns 36-44. Each of the nine columns in a group specified by a particular value of A_{C} 816 may be accessed in turn by incrementing a counter, for example in response to a multiple-column burst command.

FIG. 8B illustrates a timing diagram 820 for memory access commands directed to a memory device that stores ECC syndromes along with corresponding data in accordance with some embodiments. Addresses specified by commands 822 in the timing diagram 820 are decoded from physical addresses in accordance with the logic described in FIG. 8A. A memory access command 822-0 directed to a particular memory device (e.g., 106a) on a module includes a row access command 824 and a two-column burst command 826. The command 822-0 is followed by eight two-column burst commands 822-1 through 822-8. In response to the nine commands 822-0 through 822-8, the memory device transfers data 828-0 through 828-8 to the memory controller. The transferred data 828-0 through 828-8 corresponds to a 144B block of data including a 16B ECC syndrome. The timing diagram 820 thus illustrates a burst length corresponding to nine memory access commands 822-0 through 822-8. The burst length has been increased as compared to the burst length for the timing diagram 320 (FIG. 3B) to accommodate the transfer of data for the ECC syndrome. In some embodiments memory devices have configurable burst lengths. For example, a memory device may be configured to have a first burst length in a non-ECC mode and a second, longer burst length in an ECC mode. FIG. 3B illustrates a first burst length corresponding to eight memory access commands for a non-ECC mode and FIG. 8B illustrates a second burst length corresponding to nine memory access commands for an ECC mode. In some embodiments the burst length is configured by writing a value to a configuration register that controls or selects a burst counter.

The unused bandwidth for control signal CA0 305 in FIG. 8B may be used to direct memory access commands to other memory devices on the module 104-1. For example, groups of nine commands directing devices to output a 144B block of data including a 16B ECC syndrome can be provided to multiple devices or to each device in an interleaved manner. A group of nine subsequent memory access commands 822-9, 822-A, etc. address another row (e.g., having 144B of data) of the same memory device (e.g., 106a) and a corresponding 16B ECC syndrome.

FIG. 8C illustrates a timing diagram 840 for a configuration in which ECC syndromes are stored in a separate dedicated memory device on the module in accordance with some embodiments. In the example of FIG. 8C, memory device 106c on module 104-1 stores ECC syndromes corresponding to data words stored in the other memory devices (i.e., 106a and 106e-106o) on the module 104-1. Memory access commands 842-0 through 842-7 address a particular row in memory device 106a, resulting in the transfer of data 848-0 through 848-7 from memory device 106a to the controller 102. A memory access command 844 directs memory device 106c to transfer ECC syndrome 850, which corresponds to data 848-0 through 848-7, to the controller 102. A group of eight subsequent memory access commands 852 (only three are shown) address another row in memory device 106a, resulting in the transfer of data 856 from memory device 106a to the controller 102. A memory access command 854 directs memory device 106c to transfer ECC syndrome 858, which corresponds to data 856, to the controller 102.

The unused bandwidth for control signal CA0 305 in FIG. 8C may be used to direct memory access commands successively to other memory devices on the module 104-1 and to direct memory device 106c to transfer to the controller other ECC syndromes corresponding to data from the other memory devices. For example, the two-cycle time slots (e.g., 846) of the control path (e.g., control path CA0) following each of the commands 842-1 through 842-7 may be used to direct memory device 106c to transfer to the controller other ECC syndromes corresponding to data from memory devices 106e-106o and the remaining two-cycle slots may be used to issue memory access commands to devices 106e-106o on module 104-1.

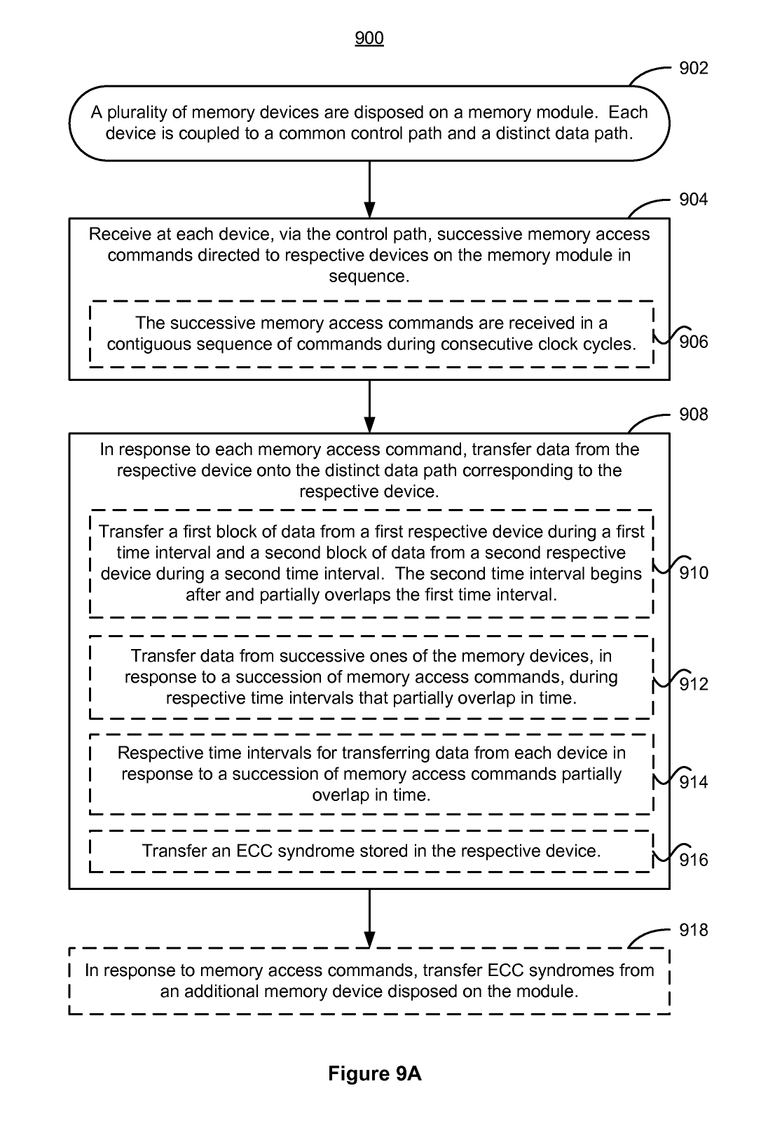

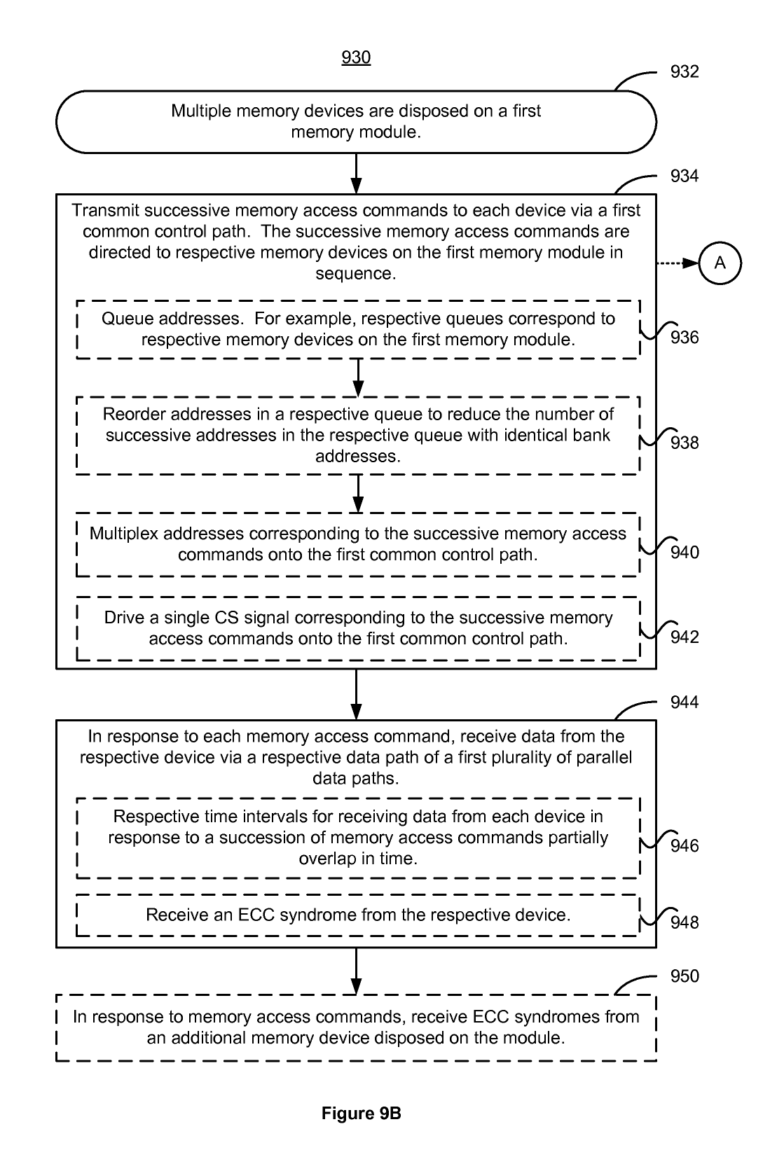

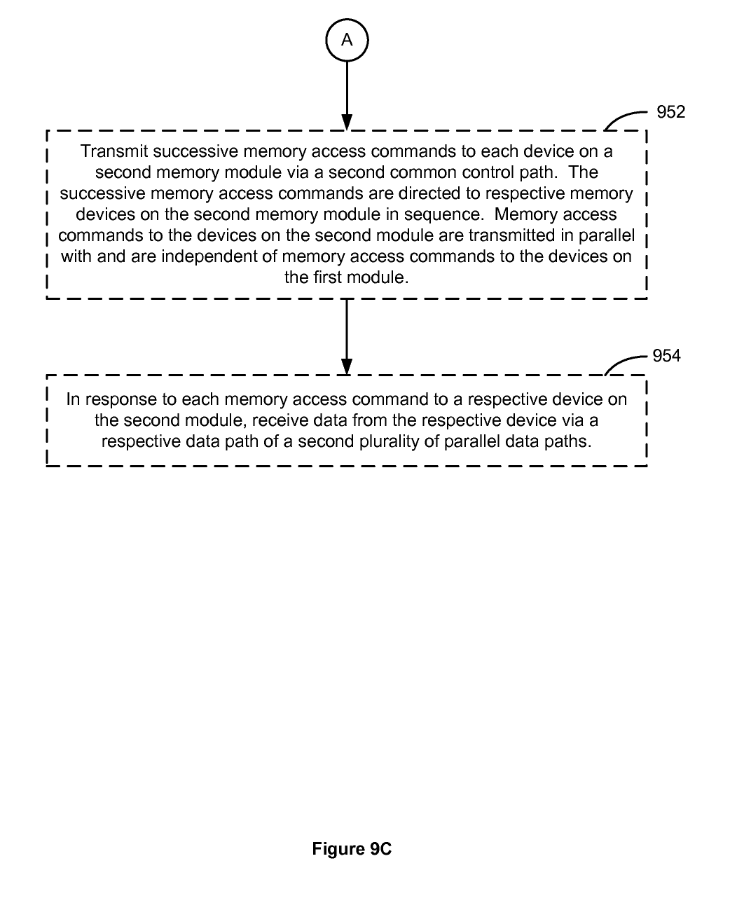

Attention is now directed to methods of operating memory modules and a memory controller. FIG. 9A is a flow diagram illustrating a method 900 of operating a plurality of memory devices disposed on a memory module in accordance with some embodiments. Each device is coupled (902) to a common control path and a distinct data path. For example, each device 106 on module 104-1 (FIG. 1A) is coupled to control path CA0 112-1 and to a distinct data path 108 (e.g., 108m for device 106m).

Each device receives (904), via the control path, successive memory access commands directed to respective devices on the memory module in sequence. In some embodiments, the successive memory commands are received (906) in a contiguous sequence of commands (e.g., sequence 346, FIG. 3C) during consecutive clock cycles.

In some embodiments, a CS signal is received at each device. A delay between receiving the CS signal and receiving a memory access command directed to a respective device corresponds to a delay for the CS signal (e.g., CS delay value 402) in the respective device.

In response to each memory access command, data is transferred (908) from the respective device onto the distinct data path corresponding to the respective device. In some embodiments, a first block of data is transferred (910) from a first respective device during a first time interval and a second block of data is transferred from a second respective device during a second time interval. The second time interval begins after and partially overlaps the first time interval. For example, the interval for transferring data word 350c-0 (FIG. 3C) from device 106c begins after and partially overlaps the interval for transferring data word 350a-0 from device 106a. In some embodiments, data is transferred (912) from successive ones of the memory devices, in response to a succession of memory access commands (e.g., successive commands in sequence 346), during respective time intervals that partially overlap in time. In some embodiments, respective time intervals for transferring data from each device in response to a succession of memory access commands partially overlap in time (916). For example, the time intervals for transferring data words 350a-0 through 350o-0 (FIG. 3C) from the devices on module 104-1 partially overlap in time.

In some embodiments, transferring data from the respective device includes transferring (916) an ECC syndrome stored in the respective device. For example, transferred data 828-0 through 828-8 (FIG. 8B) includes a 16B ECC syndrome.

In some embodiments, in response to memory access commands, ECC syndromes are transferred (918) from an additional memory device disposed on the module. For example, as illustrated in FIG. 8C, a device (e.g., 106c) may store and transfer ECC syndromes (e.g., 850 and 858) corresponding to data transferred from other memory devices on the module.

The method 900 enables each memory device on a memory module to process a distinct respective memory access command in a succession of memory access commands and to output data on the distinct data path to which the device is coupled in response to the memory access command that the device processes.

In some embodiments, the method 900 corresponds to a first mode of operation of a plurality of memory devices disposed on a memory module. In some embodiments, the memory devices are configurable to support a second mode of operation, including receiving at each device, via the control path, a succession of memory access commands; processing, at each device (e.g., every device of a memory module), each memory access command in the succession; and, in response to each processed memory access command, transferring data from each device onto the distinct data path corresponding to the device. As noted above, in the second mode of operation, the memory devices of a memory module process memory access commands in parallel and, in response to read commands, output data in parallel. In some embodiments, the second mode of operation is enabled by configuring each memory device to have an identical CS delay value 402 (FIG. 4A) or by configuring each of the six CS signals of FIG. 4B to be asserted simultaneously.

While the method 900 described above includes operations that appear to occur in a specific order, it should be apparent that the method 900 can include more or fewer operations, that two or more operations can be combined into a single operation, and that two or more of the operations can be performed in parallel. For example, memory access commands may be received in operation 904 while data corresponding to earlier memory access commands is transferred in operation 908.

FIGS. 9B and 9C are flow diagrams illustrating a method 930 of controlling memory devices in accordance with some embodiments. The method 930 may be performed by a memory controller (e.g., 102). In the method 930, multiple memory devices (e.g., devices 106) are disposed (932) on a first memory module (e.g., 104-1). Successive memory access commands (e.g., commands in the sequence 346, FIG. 3C) are transmitted (934) to each device via a first common control path (e.g., CA0 112-1). The successive memory access commands are directed to respective memory devices on the first memory module in sequence.

In some embodiments, addresses to be transmitted are queued (936). For example, queues correspond to respective memory devices on the first memory module, as illustrated for queues 610 in FIG. 6A. In some embodiments, addresses in a respective queue are reordered (938) to reduce bank interference by reducing the number of successive addresses in the respective queue with identical bank addresses, and thus to reduce bank interference. The reordering is controlled, for example, by queue management logic 612. In some embodiments, addresses corresponding to the successive memory access commands are multiplexed (940) onto the first common control path. For example, mux 614-1 multiplexes addresses from queues 610 onto CA0 112-1.

In some embodiments, addresses to be transmitted are calculated to accommodate storage of ECC data in the devices. For example, CAD 806 is calculated as described with regard to FIG. 8A.

In some embodiments, a single CS signal corresponding to the successive memory access commands is driven (942) onto the first common control path. For example, as illustrated in FIG. 5A, a CS signal 420 is asserted once for eight successive memory access commands in the sequence 346. In some embodiments, a delay between transmitting the single CS signal and transmitting a memory access command directed to a respective device corresponds to a delay for the CS signal (e.g., CS delay value 402) in the respective device.

In response to each memory access command, data is received (944) from the respective device via a respective data path of a first plurality of parallel data paths. For example, data is received from each device 106 via a respective data path 108. In some embodiments, respective time intervals for receiving data from each device in response to a succession of memory access commands partially overlap in time (946). For example, the time intervals in which data words 350a-0 through 350o-0 (FIG. 3C) are received partially overlap in time.

In some embodiments, an ECC syndrome is received (948) from the respective device. For example, received data 828-0 through 828-8 (FIG. 8B) includes an ECC syndrome.

In some embodiments, in response to memory access commands, ECC syndromes are received (950) from an additional memory device disposed on the module. For example, as illustrated in FIG. 8C, ECC syndromes (e.g., 850 and 858) are received from device 106c; the received syndromes correspond to data transferred from other memory devices on the module.

In some embodiments, successive memory access commands are transmitted (952, FIG. 9C) to each device on a second memory module (e.g., 104-2) via a second common control path (e.g., CA1 112-2). The successive memory access commands are directed to respective memory devices on the second memory module in sequence. Memory access commands to the devices on the second module are transmitted in parallel with and are independent of memory access commands to the devices on the first module. For example, commands in sequence 348 (FIG. 3C) are transmitted in parallel with and are independent of commands in sequence 346.

In response to each memory access command to a respective device on the second module, data is received (954) from the respective device via a respective data path of a second plurality of parallel data paths. For example, data 350b is received from device 106b via data path 108b and data 350d is received from device 106d via data path 108d.

In some embodiments, the method 930 corresponds to a first mode of operation of a memory controller. In some embodiments, the memory controller is configurable to support a second mode of operation that includes transmitting successive memory access commands to each memory device on the first memory module via the first common control path. The successive memory access commands are directed in parallel to each memory device. In response to each memory access command, the controller receives data from each memory device via the respective data paths. In the example of the controller 600, the second mode may be implemented through the mode control logic 613 by, for example, suspending round-robin operation of the muxes 614 and storing addresses to be issued to a particular module for successive memory access commands in a queue 610 coupled to an address interface 622 through a mux 614.

While the method 930 described above includes operations that appear to occur in a specific order, it should be apparent that the method 930 can include more or fewer operations, that two or more operations can be combined into a single operation, and that two or more of the operations can be performed in parallel. For example, memory access commands may be transmitted in operation 934 while data corresponding to earlier memory access commands is received in operation 944.

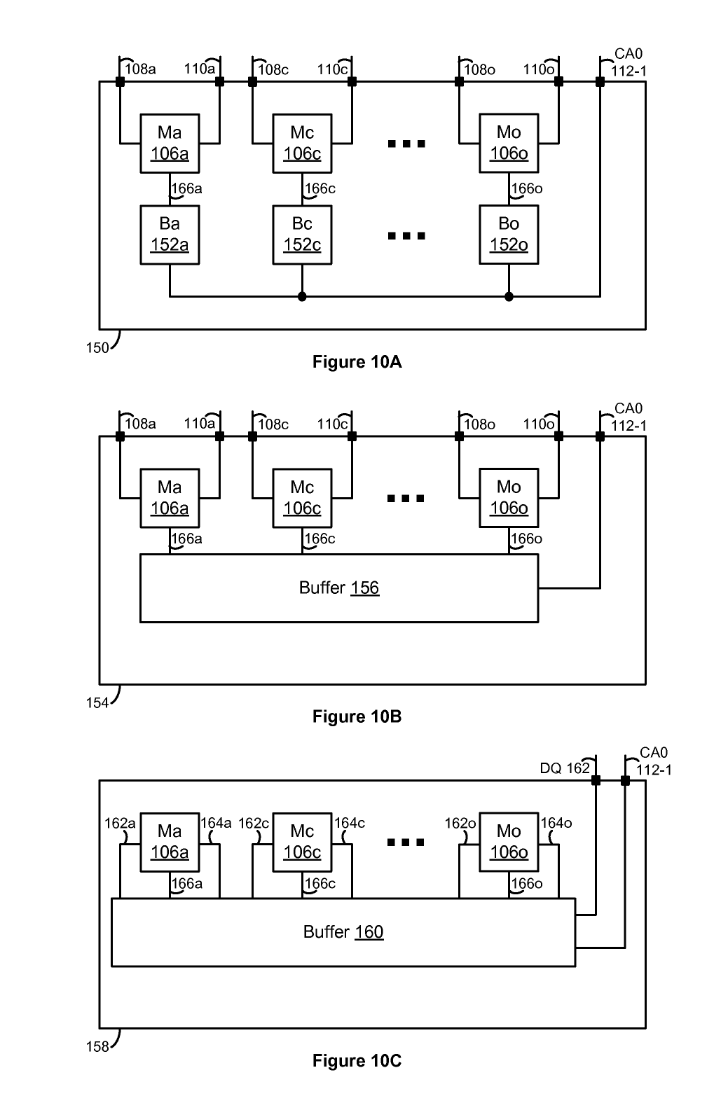

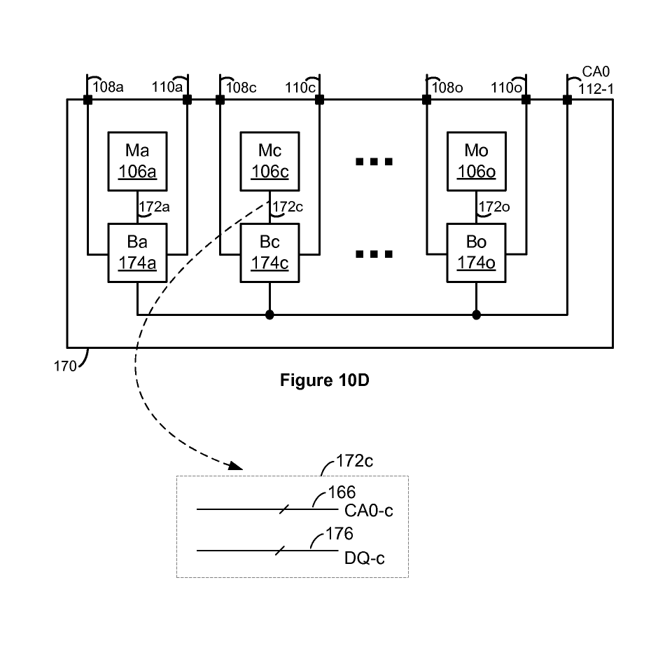

In some embodiments a memory module includes one or more buffer devices in addition to a plurality of memory devices, as illustrated in FIGS. 10A-10D in accordance with some embodiments. On the memory module 150 of FIG. 10A, each memory device 106 is coupled to the control path 112-1 through a respective buffer device 152. Each buffer device 152 receives control signals transmitted from a memory controller (e.g., 102, FIG. 1A) and provides the control signals to the respective memory device 106 through control paths 166.

In some embodiments the variable-delay CS circuitry 400 (FIG. 4A) is implemented in the buffers 152, thereby allowing the module 150 to be manufactured with memory devices 106 that do not include variable-delay CS circuitry. In some embodiments the variable delay circuitry 400 in each buffer 152 is programmed with a distinct delay value, such that the CS signal provided to each memory device 106 is delayed by a distinct number of clock cycles (the distinct number of clock cycles may be zero for one of the devices), thereby enabling each memory device 106 to process a distinct memory access command in a sequence of commands. In some embodiments the buffers 152 include burst counters to generate multiple column access commands in response to a single memory access command received via the control path 112-1. In some embodiments the number of commands generated in response to a particular received command depends on a mode setting in the buffer 152. For example, in a non-ECC mode a first number of commands (e.g., eight) are generated and in an ECC mode a second number of commands (e.g., nine) are generated, wherein the second number is greater than the first number. In some embodiments, the mode is determined by a value stored in a configuration register in the buffer 152 that is coupled to the burst counter. In some embodiments, a memory controller may set the mode by writing a corresponding value to the configuration register.

While FIG. 10A shows the buffers 152 connected to the entire control path 112, in some embodiments the buffers 152 buffer CS signals while address and command signals are provided directly to the memory devices.

In some embodiments the buffer devices buffer data as well as control signals, as illustrated in FIG. 10D for buffer devices 174 on a memory module 170. Each buffer device 174 connects to respective data paths 108 and 110 and transfers data to and from a corresponding memory device 106 via a data path 176.

In some embodiments the individual buffers 152 of FIG. 10A may be replaced with a single buffer 156 (FIG. 10B). In some embodiments the buffer 156 includes variable-delay CS circuitry 400 for each device 106. In some embodiments the buffer 156 includes a burst counter for each device 106. In some embodiments, a buffer 160 (FIG. 10C) buffers data as well as control signals: data paths 162 and 164 from each device 106 are coupled through the buffer 160 to a DQ bus 162.

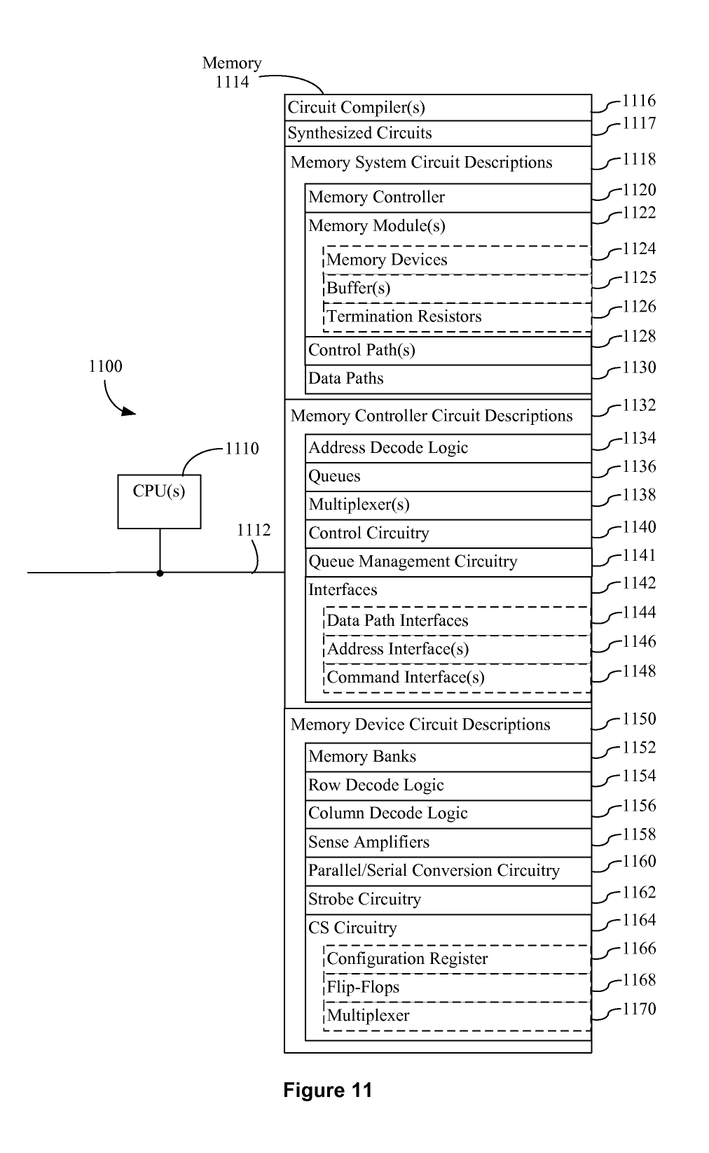

FIG. 11 is a block diagram of an embodiment of a system 1100 for storing computer readable files containing software descriptions of circuits for implementing memory systems, memory controllers, and memory devices in accordance with some embodiments. The system 1100 may include at least one data processor or central processing unit (CPU) 1110, memory 1114, and one or more signal lines or communication busses 1112 for coupling these components to one another. Memory 1114 includes high-speed random access memory, such as DRAM, SRAM, DDR RAM or other random access solid state memory devices; and may include non-volatile memory, such as one or more magnetic disk storage devices, optical disk storage devices, flash memory devices, or other non-volatile solid state storage devices. Memory 1114 may optionally include one or more storage devices remotely located from the CPU(s) 1110. Memory 1114, or alternately the non-volatile memory device(s) within memory 312, comprises a computer readable storage medium. In some embodiments, the computer readable storage medium of memory 1114 stores in one or more of the previously mentioned memory devices one or more circuit compilers 1116, memory system circuit descriptions 1118, memory controller circuit descriptions 1132, and memory device circuit descriptions 1150. The one or more circuit compilers 1116, when executed by a processor such as CPU(s) 1110, process one or more circuit descriptions to synthesize one or more corresponding circuits, labeled synthesized circuits 1117 in FIG. 11.

In some embodiments, the memory system circuit descriptions 1118 include circuit descriptions for a memory controller 1120, one or more memory modules 1122, one or more control paths 1128, and data paths 1130. In some embodiments, the circuit description for the one or more memory modules 1122 includes circuit descriptions for memory devices 1124, one or more buffers 1125, and termination resistors 1126. Alternately, circuit descriptions for a memory controller 1120 may be stored in the aforementioned computer readable storage medium, and optionally circuit descriptions for one or more memory modules 1122 may be stored in a different computer readable storage medium.

In some embodiments, the memory controller circuit descriptions 1132 include circuit descriptions for address decode logic 1134, queues 1136, one or more multiplexers 1138, control circuitry 1140, queue management circuitry 1141, and interfaces 1142. In some embodiments, the circuit descriptions for the interfaces 1142 include circuit description for data path interfaces 1144, one or more address interfaces 1146, and one or more command interfaces 1148. Alternately, memory controller circuit descriptions 1132 include a subset of the aforementioned circuit descriptions, and may optionally include additional circuit descriptions.

In some embodiments, the memory device circuit descriptions 1150 include circuit descriptions for memory banks 1152, row decode logic 1154, column decode logic 1156, sense amplifiers 1158, parallel/serial conversion circuitry 1160, strobe circuitry 1162, and CS circuitry 1164. In some embodiments, the circuit description for CS circuitry 1164 includes circuit descriptions for a configuration register 1166, flip-flops 1168, and a multiplexer 1170. Alternately, memory device circuit descriptions 1150 include a subset of the aforementioned circuit descriptions, and may optionally include additional circuit descriptions.

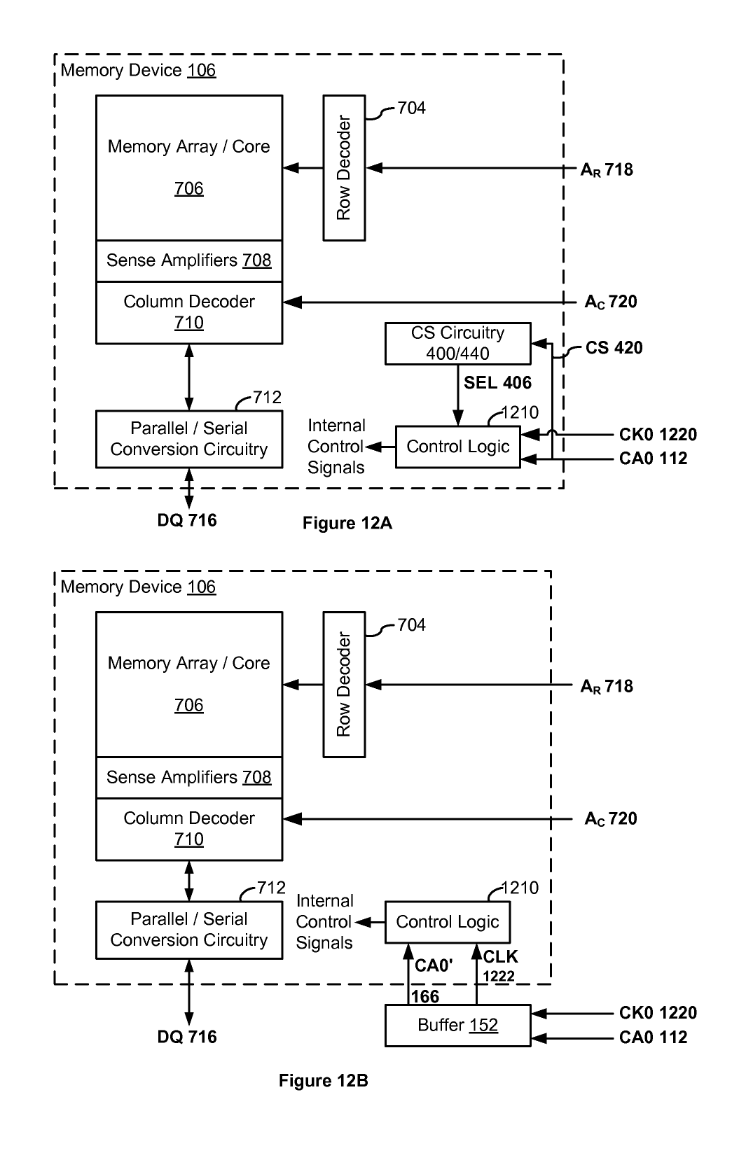

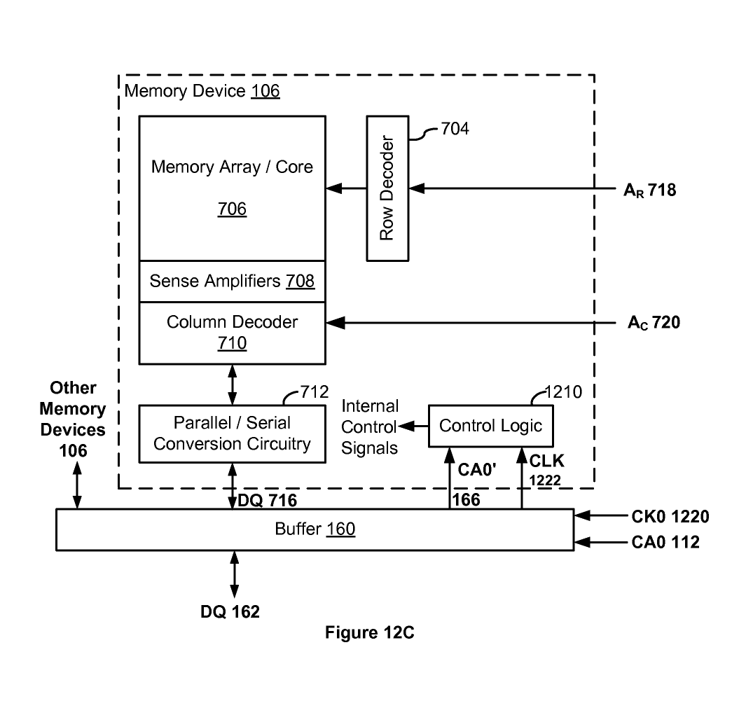

FIGS. 12A-12C are block diagrams illustrating memory devices 106 in accordance with some embodiments. In FIG. 12A the memory device 106 includes CS circuitry 400 or 440 of FIGS. 4A-4B, which generates a SEL signal 406. If the control logic 1210 receives a memory access command from the control path 112 while SEL 406 is asserted, it generates internal control signals to enable the memory device 106 to execute the memory access command.

In FIGS. 12B and 12C, the memory device 106 does not include CS circuitry 400 or 440. Instead, in some embodiments a buffer 152 or 160 includes circuitry equivalent to CS circuitry 400 or 440, such that the SEL signal generated in the buffer 152 or 160 is provided as a CS signal to the memory device 106 via a control path 166. If the control logic 1210 receives a memory access command (e.g., via the control path 166) while the CS signal received via the control path 166 is asserted, it generates internal control signals to enable the memory device 106 to execute the memory access command. In the example of FIGS. 12B and 12C, the buffer 152 or 160 buffers a clock signal CK0 1220, to be provided to the memory device 106 as CLK 1222. Alternatively, a clock signal may be provided directly to the memory device 106. Buffers 152 and 160 are described further with regard to FIGS. 10A and 10C, above.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

1. (canceled)

2. A memory module having external link connections over which to receive memory access commands and respective incoming data, comprising:
circuitry to buffer the memory access commands received from the external link connections; and
a plurality of dynamic random access memory (DRAM) devices;
wherein the circuitry is to route the incoming memory access commands in association with the respective incoming data to respective ones of the DRAM devices.

3. The memory module of claim 2, wherein:
the plurality includes at least four of the DRAM devices.

4. The memory module of claim 3, wherein:
the circuitry is to route the memory access commands and respective incoming data to corresponding ones of the at least four of the DRAM devices, on a round robin basis.

5. The memory module of claim 2, wherein:
each memory access command includes an address of one of the DRAM devices; and
for each memory access command, the circuitry is to route the memory access command to one of the plurality of DRAM devices according to the address of the one of the DRAMS.

6. The memory module of claim 5, wherein:
each DRAM device comprises banks of memory;
each of the memory access commands is to be routed to one of the banks of memory of one of the plurality of DRAM devices; and
each memory access command further includes a memory bank address, a row address and a column address, the memory bank address corresponding to one of the banks of memory in the DRAM device to which the memory access command is to be routed.

7. The memory module of claim 2, wherein:
the memory module comprises a register to store a setting;
the memory module is to operate in a selective one of a first mode and a second mode according to the setting;
in the first mode, the circuitry is to route the memory access commands to respective ones of the DRAM devices together with the respective incoming data; and
in the second mode, the circuitry is to route each memory access command in common to all of the DRAM devices.

8. The memory module of claim 2, wherein:
each DRAM device is characterized by a time interval before a second memory access command can be directed to a same array of the DRAM device as a first memory access command;
the plurality of DRAM devices in number less than or equal to a number of command time slots corresponding to the time interval.

9. The memory module of claim 2, wherein:
each DRAM device is characterized by a time interval before a second memory access command can be directed to a same array of the DRAM device as a first memory access command;
the plurality of DRAM devices in number less than or equal to a number of command time slots corresponding to the time interval.

10. The memory module of claim 2, embodied as a dual in-line memory module (DIMM) having edge contacts, each of the edge contacts operable to exchange data externally at a data rate of no less than 3.2 gigabits per second.

11. The memory module of claim 2, wherein:
the memory module further comprises edge contacts defining a path to receive the memory access commands from the external link connections, and edge contacts defining a path to receive the respective incoming data from an external source; and
the path to receive the memory access commands from the external source is distinct form the path to receive the respective incoming data from the external source.

12. The memory module of claim 2, wherein:
the circuitry is also to buffer the respective incoming data and is to route the incoming memory access commands and the respective incoming data to respective ones of the DRAM devices.

13. The memory module of claim 12, wherein:
each memory access command includes an address of one of the DRAM devices; and
for each memory access command, the circuitry is to route the memory access command and the respective incoming data to one of the plurality of DRAM devices according to the address of the one of the DRAMS.

14. The memory module of claim 12, wherein:
the memory module comprises a chip select path and data path dedicated to each DRAM device which couples the circuitry with each DRAM device.

15. The memory module of claim 2, wherein:
the circuitry to buffer comprises circuitry to generate multiple column access commands in response to a single memory access command received from the external link connections.

16. The memory module of claim 15, wherein the multiple column access commands are routed to respective ones of the DRAM devices in response to the single memory access command.

17. The memory module of claim 15, wherein:
the memory module is operable in an error correction coding (ECC) mode and a non-ECC mode;
when the memory module is operated in the ECC mode, the circuitry to generate multiple column access commands is to generate a first number of column access commands in response to a single memory access command; and
when the memory module is operated in the non-ECC mode, the circuitry to generate multiple column access commands is to generate a second number of column access commands in response to the single memory access command, the second number being greater than the first number.

18. A memory module having external link connections over which to receive memory access commands and respective incoming data, comprising:
circuitry to buffer the memory access commands and the respective incoming data received from the external link connections; and
a plurality of dynamic random access memory (DRAM) devices, each DRAM device characterized by a time interval before a second memory access command can be directed to a same array of the DRAM device as a first memory access command;
wherein
the circuitry is to route the incoming memory access commands and respective incoming data to respective ones of the DRAM devices, and
the circuitry is to route at least two of the incoming memory access commands and respective incoming data during the time interval.

19. The memory module of claim 18, wherein:
each memory access command includes an address of one of the DRAM devices; and
for each memory access command, the circuitry is to route the memory access command to one of the plurality of DRAM devices according to the address of the one of the DRAMS.

20. The memory module of claim 18, wherein:
each DRAM device comprises banks of memory;
each of the memory access commands is to be routed to one of the banks of memory of one of the plurality of DRAM devices; and
each memory access command further includes a memory bank address, a row address and a column address, the memory bank address corresponding to one of the banks of memory in the DRAM device to which the memory access command is to be routed.

21. A memory module having external link connections over which to receive memory access commands and respective incoming data, comprising:
circuitry to buffer the memory access commands received from the external link connections;
a register to store a setting; and
at least four dynamic random access memory (DRAM) devices, each DRAM device characterized by a time interval before a second memory access command can be directed to a same array of the DRAM device as a first memory access command;
wherein
the circuitry is to route the incoming memory access commands in association with the respective incoming data to respective ones of the DRAM devices,
the memory module is to operate in a selective one of a first mode and a second mode according to the setting,
in the first mode, the circuitry is to route the memory access commands to respective ones of the DRAM devices together with the respective incoming data, and
in the second mode, the circuitry is to route each memory access command in common to all of the DRAM devices.
